(19) United States
(12) Patent Application Publication
(10) Pub. No.: US 2011/0211604 A1
(43) Pub. Date: Sep. 1, 2011

(54) Completely Self-Adjusted Surface-Emitting Semiconductor Laser For Surface Mounting Having Optimized Properties

(75) Inventor: Ralf-Hendrik Roscher, Ulm (DE)

(73) Assignee: UNIVERSITÄT ULM, Ulm (DE)

(21) Appl. No.: 12/991,571

(22) PCT Filed: May 5, 2009
(86) PCT No.: PCT/EP2009/003213

§ 371 Date: Mar. 24, 2011

(30) Foreign Application Priority Data
May 8, 2008 (DE) 10 2008 022 793.5

(51) Int. Cl. H01S 5/42; H01S 5/183; H01S 5/24; H01S 5/024; H01L 33/24

(52) U.S. Cl. 372/35; 372/44.011; 372/36; 438/40; 257/E33.006

(57) ABSTRACT

The present invention relates to a surface-emitting semiconductor laser having a vertical resonator, comprising a substrate base section (1) and a mesa (M) arranged on and/or at the substrate base section, the mesa substantially comprising, viewed perpendicular to the substrate base section: at least one part of a first doting region (2) facing the substrate base section, at least one part of a second doping region (4) facing away from the substrate base section, and an active region (3) arranged between the first and the second doping regions, said active region having at least one active layer (A) with a laser-emitting zone, emitting substantially perpendicular to the active layer, characterized in that the mesa (M) comprises in at least one partial section of the side flank thereof at least one constriction (E).

The present invention relates to surface-emitting semiconductor lasers, systems or arrays composed of such surface-emitting semiconductor lasers, and methods for manufacturing such surface-emitting semiconductor lasers and semiconductor laser arrays.

Surface-emitting semiconductor lasers, also referred to below as vertical laser diodes or vertical cavity surface-emitting lasers (VCSEL), are a new type of semiconductor laser diode whose development at the Institute for Optoelectronics, University of Ulm, in the 1990s was initiated and continued by Prof. K. J. Ebeling, and which at the present time is primarily being conducted under the supervision of Dr.-Ing. R. Michalzik. For approximately the last ten years these lasers have been manufactured on the industrial scale in many different versions, with increasing commercial success. In particular, in the past three years the demand for VCSELs has multiplied with annual growth rates of 100 to 200%. Due to their special properties they are continually opening up new fields of application. At the present time they are manufactured in annual quantities of several million units by numerous companies, among them the Ulmer spin-off company U-L-M photonics GmbH.

The fields of application start with highly specialized use in parallel optical data connections which are currently used to further accelerate distributed computing in the world's most powerful computers, the supercomputers, but which have the potential, with a decrease in manufacturing costs, to replace copper-based bus systems in standard computing technology, and thus open up the computer mass market. Another huge market, which however is extremely sensitive to cost, is the automotive industry. In the near future, lasers which typically emit in the near-infrared range will be providing many fields of application for sensor systems due to driver assistance systems which are being increasingly developed, such as blind spot monitoring or collision recognition. As a result, data streams will also greatly increase in ever more intelligent automobiles, which will create a demand for sensor system VCSELs as well as data transmission VCSELs in automobiles. Consumer products such as optical computer mice, for example, represent another mass market for VCSEL, so that, due to the enormous cost pressure, long-term survival of a VCSEL manufacturer can be ensured only by continuous advances in productivity.

However, the discussion of the demands of future mass applications makes it clear that conventional manufacturing strategies are inadequate with regard to performance as well as cost. In addition to the reduction in space consumption, there is a great potential for a fundamental change in process technology toward completely self-adjusted VCSEL structuring, which is already customary for other modern semiconductor components.

VCSELs are components which are subject to power loss and at the same are sensitive to temperature. In many applications, a large number of these lasers are housed in a very compact space, and are also integrated with driver chips, which likewise result in power loss. Therefore, a thermal problem exists. Furthermore, the components attain the high required modulation speeds only at high pump flow rates, i.e., in operating states in which there is comparatively great heat loss. In addition, due to the complex layer structure of the VCSEL itself, satisfactory heat dissipation in the prior art has been lacking.

The object of the present invention, therefore, based on the prior art, is to provide surface-emitting semiconductor lasers or semiconductor laser elements and arrays from such semiconductor lasers which show improved heat dissipation capability, allow higher operating speeds, have improved conversion efficiency, and have a longer service life as well as a higher maximum output—in brief, which in comparison to the semiconductor laser elements known from the prior art have improved efficiency. A further object is to provide manufacturing methods for such surface-emitting semiconductor laser elements or semiconductor laser arrays.

The object is achieved by a surface-emitting semiconductor laser element according to Claim 1, a system composed of such semiconductor laser elements according to Claim 22, and a manufacturing method according to Claim 39. Advantageous embodiments result from the respective dependent claims. Claim 44 also describes uses according to the invention.

The present invention is first described in general terms. This is followed by two specific embodiments which are first described with regard to their structural-physical design. The two exemplary embodiments are then described in detail with regard to the mode of operation of the illustrated surface-emitting semiconductor laser element, with regard to the advantages of the surface-emitting semiconductor laser element according to the invention, and with regard to the manufacture of the surface-emitting semiconductor laser element according to the invention.

The aspects of the present invention which are described in the individual exemplary embodiments may occur not only in the particular combination specifically described, but, within the scope of the present invention on the basis of the expertise of one skilled in the art, may also be carried out and used in other combinations.

In the present invention, the term “substrate” or “substrate base section” generally refers to a carrier, a base, and/or a supporting structure of any given shape and material. Thus, the substrate may be designed as a flat semiconductor wafer made of Si or GaAs, or as a three-dimensionally structured support made of plastic, for example.

The basic concept of the present invention involves designing the mesa of the surface-emitting semiconductor laser element in a completely novel way, namely, by providing a constriction or multiple constrictions in the side flank of the mesa. In this regard, a constriction is understood to mean a region of the mesa in which the mesa, viewed in the direction essentially perpendicular to the direction of emission or essentially parallel to the substrate plane, has a decreased cross-sectional area compared to mesa regions situated above and below same (viewed in the direction of emission). In particular, in the narrower sense the term “constriction” is understood to mean the section of the mesa at the level at which the mesa has the smallest surface area (for a circular mesa viewed in the cross section, parallel to the substrate layer plane, in the direction of emission, for example, this would be the level at which the mesa has the smallest diameter). In other words, an indentation or a lateral etching is provided for the mesa of the surface-emitting semiconductor laser element according to the invention, thus removing material which forms the mesa from the side flank of the mesa at the level of the constriction.

Another important aspect of the present invention is the novel design of the flip chip integration of the semiconductor laser which is based on the above-described constriction, i.e., provision of a completely novel way of bordering the semiconductor laser by a three-dimensionally structured substrate or a three-dimensionally structured supporting element.

The two aforementioned important aspects of the present invention, which are described in detail below with reference to exemplary embodiments, have the following advantages over the prior art:

The VCSELs according to the invention, also referred to below as XCSELs due to the constriction according to the invention (for example, X-shaped Cavity Surface-Emitting Laser or also eXtended Capabilities SEL), represent a new level of monolithic VCSEL technology. For various applications they offer completely novel approaches to advances in manufacturing productivity which heretofore were believed to be unattainable. This is achieved without, for example, having to settle for compromises in component performance; on the contrary, a (sometimes dramatic) improvement in component performance results. For example, in initial testing of flip chip-integrated XCSEL arrays, the values for thermal resistance were lower than the previous best international value by approximately 50% for lasers of this design, and were even approximately 70 to 80% lower than commercially marketed products. As the result of a 50% reduction, the lasers become only half as warm under comparable operating conditions, which is even more important in light of the fact that they are generally thermally limited with regard to their critical performance parameters and service life.

Thus, the present invention opens up tremendous advances in productivity as well as new possibilities for superior thermal management. As shown by the example of substrate-remote high-speed VCSEL for data transmission, the transmission rates may be significantly increased by using XCSELs. The proposed technology is also of interest for high-performance VCSEL due to the improved cooling. From a technological standpoint, it is possible for the first time to carry out completely self-adjusted manufacture of complete VCSELs, optionally even including the p-side flip chip connection. Despite the introduction of additional elements, process steps are entirely eliminated, and the remainder are streamlined. The VCSELs are provided with new, optimized geometries which not only improve the component properties but also provide technological tools in different variants, in particular as built-in lithography and shadow masks.

The following advantages in particular are achieved:
The constriction in the mesa, i.e., the diabolo-like mesa shape, results in minimization of the oxidation length (and the resulting capacitances), while at the same time limiting the scattering losses at the mesa walls.
The geometry according to the invention allows efficient current injection and heat dissipation at the side wall, directly at the active zone, with optimum bypassing of the Bragg reflectors. The precision achieved as the result of the mesa shape allows separate side wall metal plating for the n and p sides without insulating layers or passivation layers (typically SiNₓ) therebeneath, thus allowing not only unhindered heat flow laterally from the active zone, from the semiconductor directly into the side wall metal having high thermal conductivity, but at the same time also allowing direct lateral current injection directly above or below the active zone. Compared to the prior art, this results in higher speeds, lower operating temperatures, longer service lives, higher maximum power output, improved conversion efficiencies, and therefore better overall efficiency.
The geometry of the XCSELs, which is optimized for performance, at the same provides the essential tool for manufacturing the lasers themselves. This results in greatly reduced complexity in manufacturing and improved yield: additional elements and more complex geometries provide expanded functionalities and improved performance parameters with simplified manufacture.
XCSEL shaping in a single etching step which includes the entire layer structure, compared to multilayer mesa etching carried out heretofore.
Reduced number of process steps and process time→shorter throughput times.
Completely self-adjusted structures→increased precision, shorter throughput times.
Elimination of manual processes in favor of easily automated processes.
Visual in situ verifiability of the more cost-effective wet etching processes. Dry etching is possible for manufacture of XCSELs, but the processes are more expensive, and in most cases the mesa shapes obtained are less suitable.

When the XCSELs according to the invention are flip chip-integrated, in particular the following new possibilities for flip chip integration are obtained:
Greatly improved cooling of the lasers in the overall module as the result of
   Heat transport directly from the active zone to the well-coolable, optically bound side while bypassing the Bragg reflectors (complete enclosure of the n side with a heat dissipator composed of thermal high-performance layers, also referred to below as a cooling probe).
   Enclosing the p-side mesa with metals of the soldered connection having good thermal conductivity (mesa partially inside the solder ball). Thus, for the first time heat distribution layers (heat dissipators) have been implemented which collect the heat directly from the inner cavity of the lasers on the epitaxial side and conduct it to the optically bound substrate side, where it is freely accessible over a large surface area for a cooling air stream, for example. Thus, they represent a shunt which bridges the substrate-side Bragg reflector stack (also referred to below as “distributed Bragg reflector” (DBR)). In previous flip chip-integrated, substrate-remote VCSELs from the prior art, all structures for the contacting remain on the epitaxial side, on which, however, the electronics system which likewise generates heat is located, which hinders the heat dissipation from the laser due to the lack of temperature gradients, which may heat the laser even further. In contrast, passive optical elements such as lenses or glass fibers result in no heat loss on their own, for which reason the heat loss from the laser may be discharged very well on the optically bound side in the direction of a relatively large negative temperature gradient. The structure according to the invention thus has heat distributors which begin on the substrate side with submicron precision, directly at the active layers, and from the epitaxial side change to a large exposed surface.
Integrated self-adjusted fiber guiding
   Simultaneous alignment of optical elements (fibers of a fiber bundle or microlens array, for example) for cost-effective mounting and reproducible and homogeneous properties of the coupling sites.
   Suppression of back-reflections by using index matching for further improvement of the dynamics.
   Possibility for targeted inflow of a cooling gas to the lasers from longitudinal openings in the fiber or fiber bundle.
Efficient through contacting of the emission side for the electrical connection
   Better bond pad wetting in the reflow soldering operation.
   Additional positive fit of the soldered connection.
   Reduced structural discontinuities, and force flows which are more spatially balanced.
   Increased service life.
Self-planarizing flip chip technology for bridging the height differences of the nonplanar design.

Thus, improved performance with reduced manufacturing complexity also results for the flip chip integration.

The present invention is described in detail below with reference to two exemplary embodiments (the structure of an individual surface-emitting semiconductor laser according to the invention is described first, followed by the description of its mode of operation, then the description of the structure of a flip chip-integrated array according to the invention of surface-emitting semiconductor laser elements according to the invention, and lastly, the description of the mode of operation of the latter).

The figures show the following:

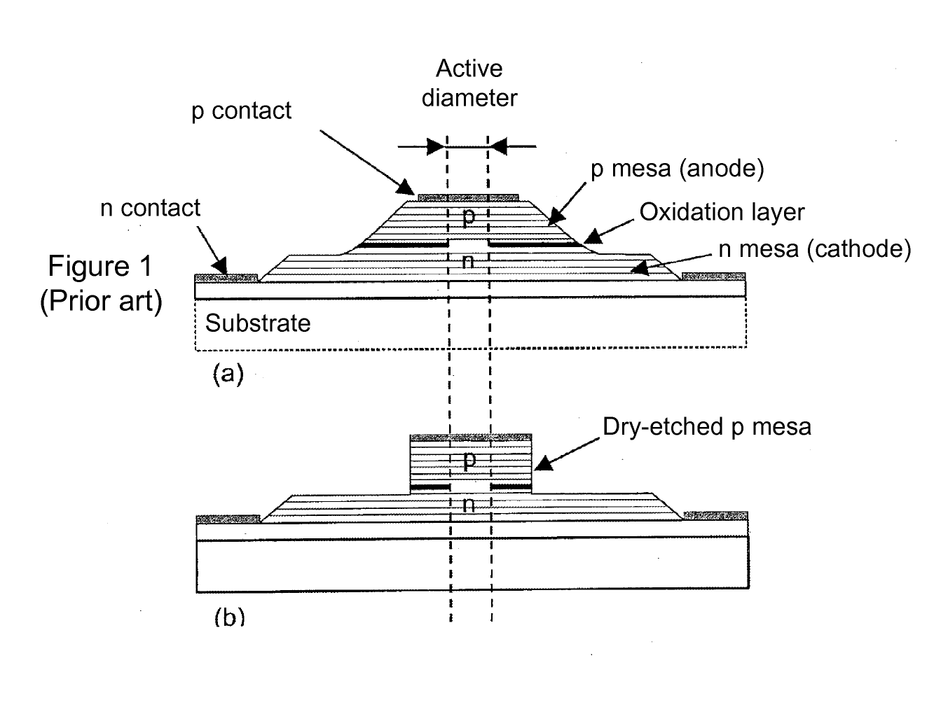

FIG. 1 shows surface-emitting semiconductor laser elements according to the prior art.

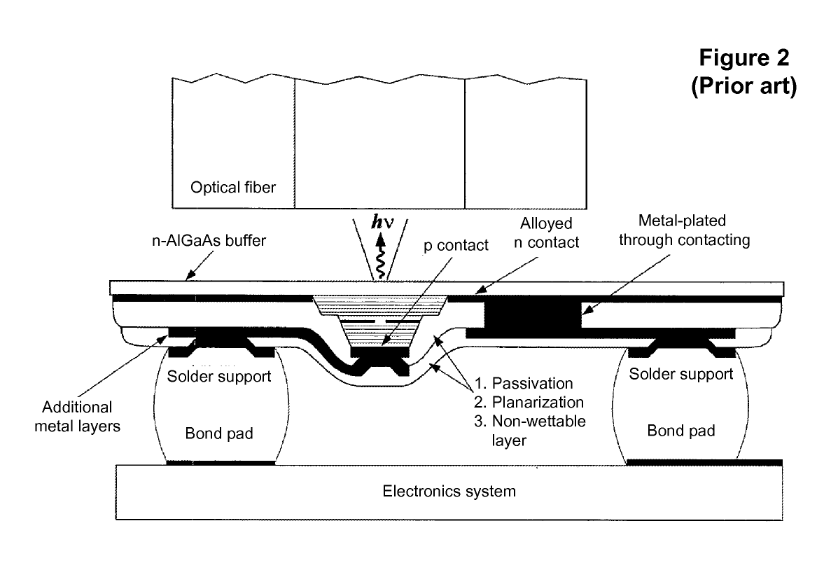

FIG. 2 shows the flip chip integration of a surface-emitting semiconductor laser element according to the prior art.

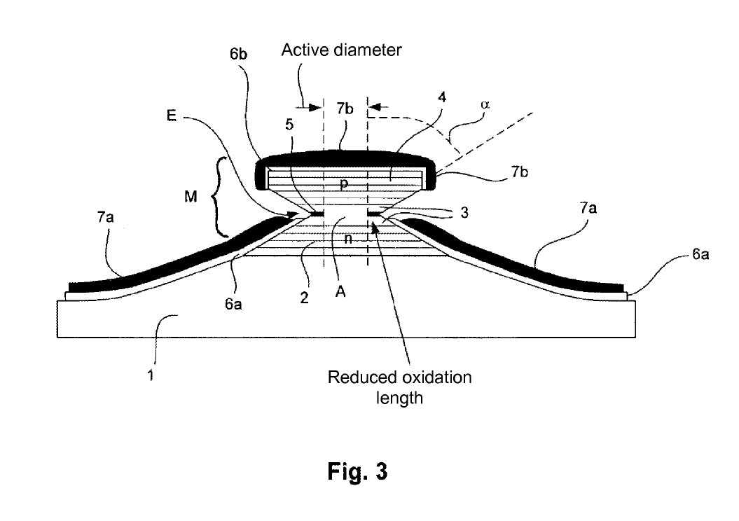

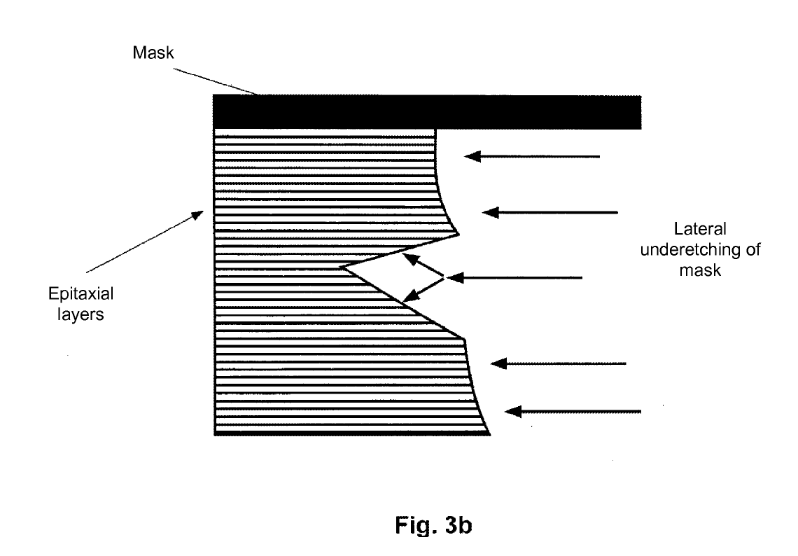

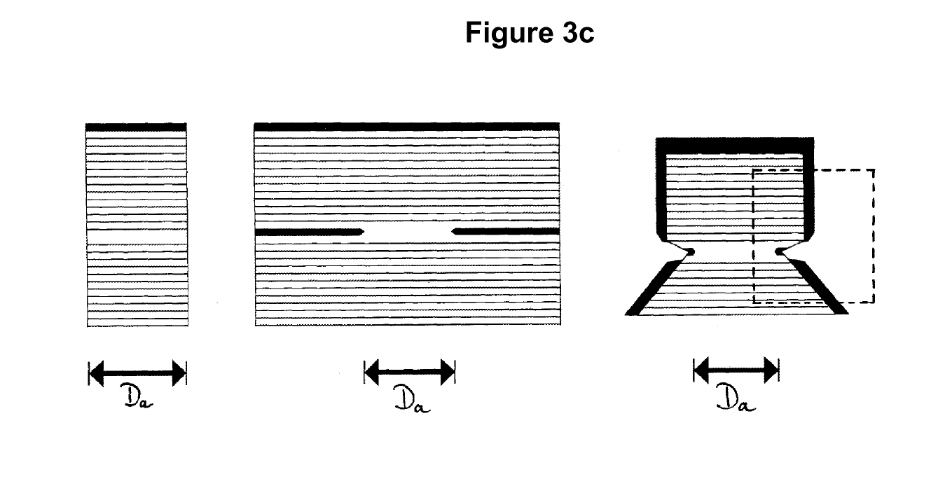

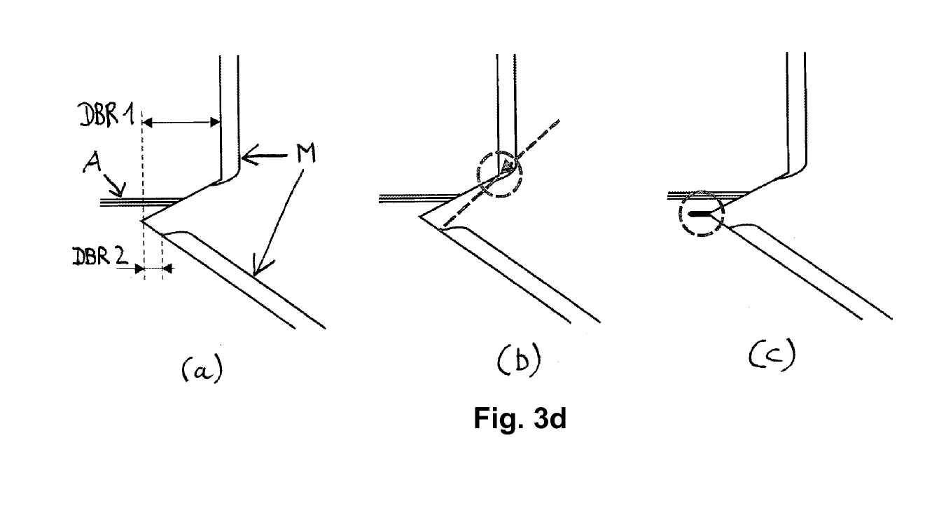

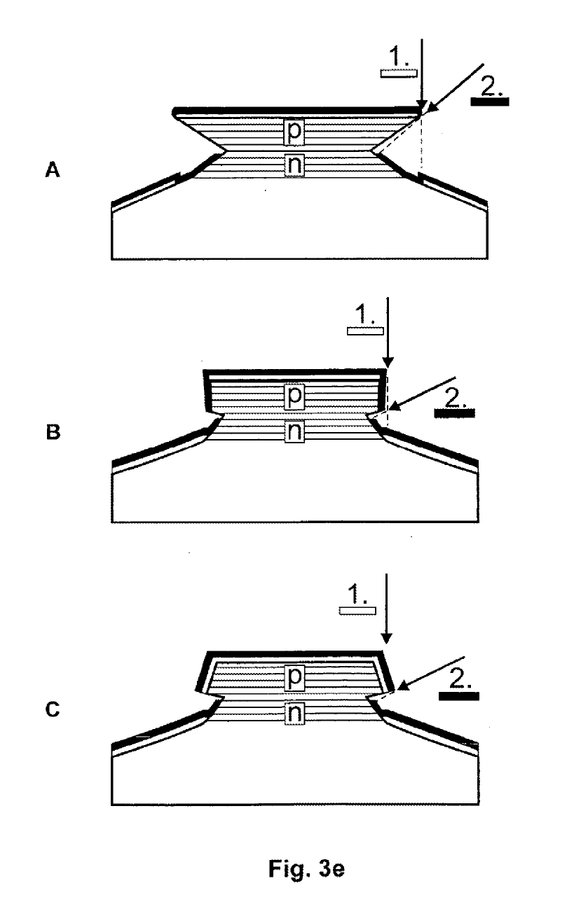

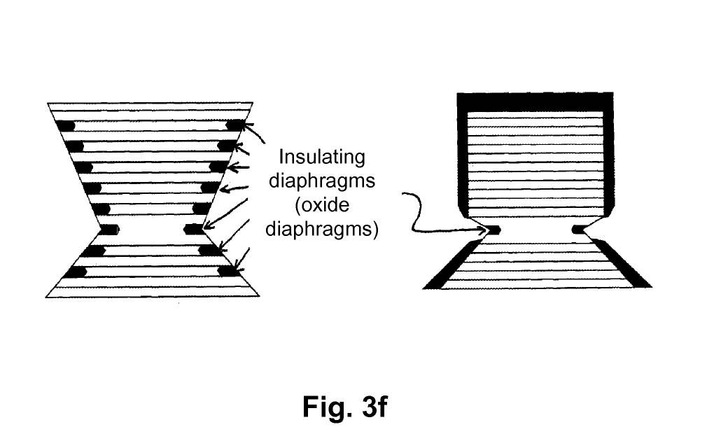

FIG. 3 shows an individual surface-emitting semiconductor laser element according to the invention, which according to the invention has a constriction in its mesa side flank.

FIGS. 3b through f show variants of the invention as shown in FIG. 3a, comparisons of the invention to the prior art, and/or manufacturing steps within the scope of the present invention.

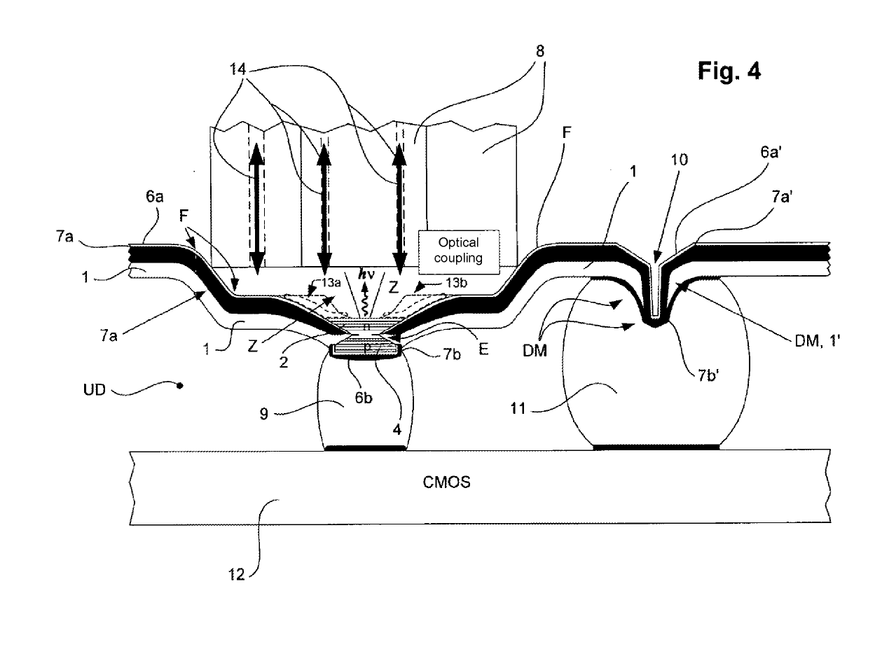

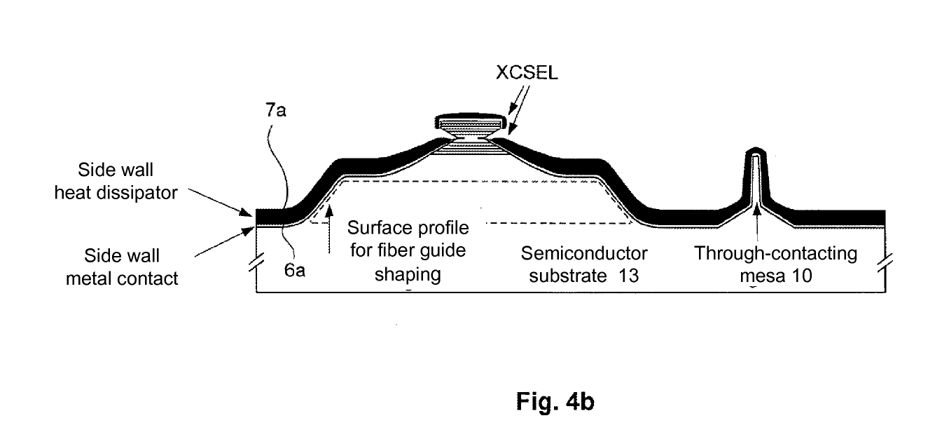

FIG. 4 shows the flip chip integration of surface-emitting semiconductor laser elements according to the present invention.

FIG. 4b shows an intermediate step in the manufacture of the element shown in FIG. 4a.

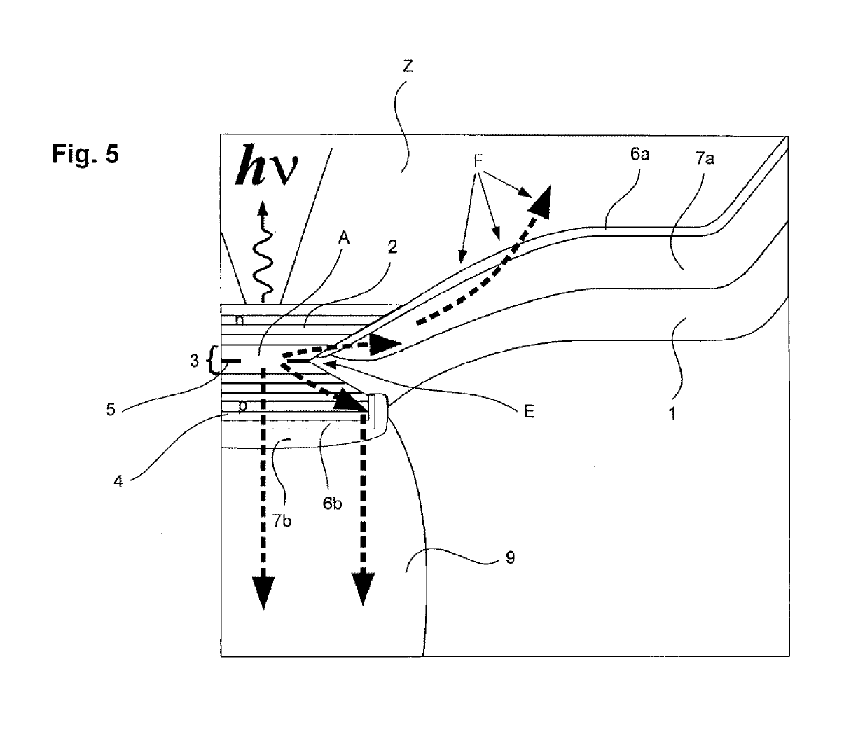

FIG. 5 shows a detail from FIG. 4.

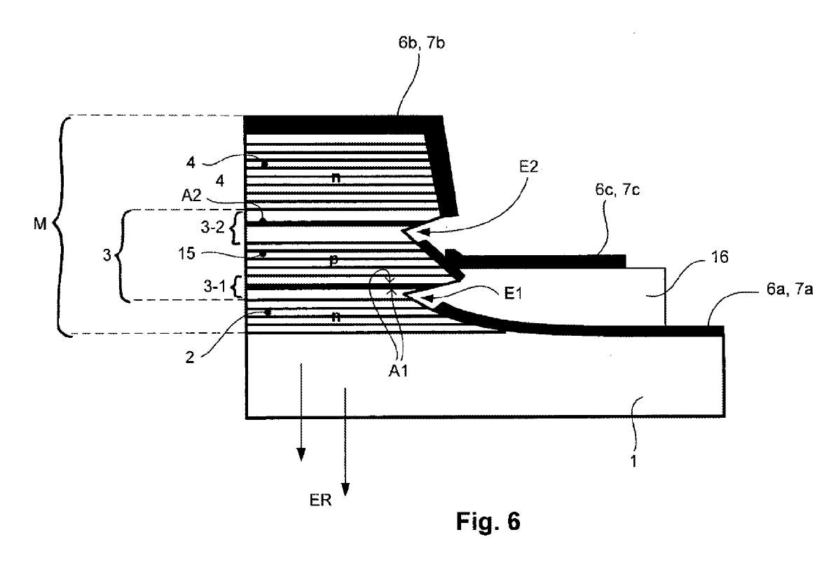

FIG. 6 shows a variant of the invention having multiple indentations or constrictions.

FIG. 1 shows two surface-emitting semiconductor laser elements as known from the prior art. As shown in FIG. 1(a), it is known from the prior art to form a mesa of the surface-emitting semiconductor laser element in the form of two superposed, stacked truncated cones centered on a common axis. The n mesa region (which is situated on the substrate, facing same) provided as the cathode has a larger average diameter (viewed parallel to the substrate plane) than the upper p mesa region which is provided as the anode. This results in two superposed table-shaped mesa regions having side walls or side flanks which are inclined with respect to the direction of emission. However, an n-on-p design with reversed polarity (i.e., doping of the upper side as n-conductive) is also possible.

FIG. 1(b) shows another example in which the n mesa region has the same design as shown in FIG. 1(a). In this case, however, the p mesa region adjoining same, on the side of the n mesa region facing away from the substrate, has the shape of a flat cylinder (i.e., with side flanks or side walls parallel to the direction of emission and perpendicular to the substrate layer plane). This design of the p mesa is achieved by dry etching.

FIG. 2 shows the manner in which such a surface-emitting semiconductor laser element (in this case, illustrated using the example of the element shown in FIG. 1(a)) may be flip chip-integrated. The extensive, complicated planarization required in the prior art, using multiple additional metal plating and passivation levels, is clearly seen.

FIG. 3 shows, in contrast, a first example of a surface-emitting semiconductor laser according to the invention. The laser has a mesa M on a substrate base section 1, in the present case having the shape of a very flat truncated cone (however, section 1 may also be flat). The mesa M includes a first doping region 2, facing the substrate base section, which in the present case is designed as an n-doped region situated directly on the substrate base section 1 and adjoining same. The active region 3 of the mesa M is situated on the n-doped region 2, immediately adjacent thereto on its side facing away from the substrate base. This active region 3 has at least one active layer A having a laser-emitting zone which emits essentially perpendicularly to the active layer or to the substrate layer plane 1 (i.e., in the vertical direction in the diagram). The active layer, i.e., zone A, in the present case is composed of one to five quantum films, although it may also contain quantum wires or quantum points or be a bulk material. The second doping region 4 of the mesa M is situated immediately adjacent to active region 3, on its side facing away from the substrate base. The mesa is designed as a p-doped region. The n-doped region 2 and the p-doped region 4 each have a Bragg reflector stack, as is known to one skilled in the art.

According to the invention, as described below the mesa M has a constriction E of its side flanks (these are the sections of the mesa M which are not parallel to the substrate layer plane 1): As described in greater detail below, a material section has been removed or ablated from the side flank of the mesa M over the entire circumferential region of the mesa M in such a way that, viewed in the cross section perpendicular to the substrate layer plane (and through the center axis of the mesa M, which in the present case is rotationally symmetrical), a V-shaped indentation results such that at the level of the active layer A of the active region 3, the mesa M has a region (indentation region E) in which the diameter of the mesa, viewed parallel to the substrate layer plane, is approximately one-half the average diameter of the n-doped region 2 or of the p-doped region 4. In the present case, the V-shaped indentation is situated at the level of the active layer, but the narrowest point of the indentation E is located in the first reflector layer of the upper DBR adjoining the active region. Thus, at this location several epitaxial layers (approximately 100 to 300 nm) are situated above the quantum films in which the light is generated. With reversed polarity of the lower and upper mesa sections, the narrowest point would then be correspondingly situated below the active layer.

The mesa M comprising elements 2, 3, and 4 may thus be approximately described as a geometric body composed of two truncated cones which, centered with the cover surfaces having the smaller diameter for the particular truncated cone, adjoin one another. Thus, for the mesa M this results in a diabolo-shaped design, or a design which, viewed in the cross section perpendicular to the substrate layer plane and through the central rotational axis of the mesa, has an essentially X-shaped design.

In detail, the n-doped region 2 is designed as a truncated cone, and the p-doped region 4 on its side facing the n-doped region 2 is likewise designed as a truncated cone, which on the side facing away from the n-doped region 2 adjoins a flat cylinder having a diameter corresponding to the base diameter of the truncated cone. The cylinder is likewise part of the p-region. This flat cylinder is usually present, although this is not absolutely necessary. If the indentation is etched more deeply, the upper part still consists of a truncated cone. In such a variant, the average distance of the optical field in the resonator from the side walls is greater, since the upper part of the walls also extends further outward.

Due to the fact that the mesa diameter in the region of the constriction E (which represents the region of the smallest diameter of the mesa) is approximately one-half as large, at the level of the active layer A this results in approximately one-fourth the cross-sectional area of the mesa M compared to the cross-sectional area in the region of the two Bragg reflector stacks 2 and 4.

In the illustrated case, the indentation has a lateral depth of approximately 5 μm. A preferred value range is 0.5 to 10 μm, but preferred depths are between 1 and 6 μm. In the present case the side walls extend at an angle of ±30° relative to the horizontal, from the center outward; naturally, this angle may be varied, in particular via the etching rate differentials between the involved layers (etching rate difference between quick-etching and slow-etching layers). The oxidation length is only a few microns, typically approximately 2 μm, but may be less than 1 μm, or even 0 μm.

In general, the following applies:

The lateral depth of the indentation is limited by the mesa height and the maximum achievable angles. The depth of the oxidation layer should be just great enough to adequately reduce scattering losses at the mesa indentation. Both elements should keep the optical field at a sufficient distance from the metal-plated side walls, since increased losses would otherwise occur at that location, not only from scattering, but also due to induced currents. Consequently, the lateral extensions of these elements are primarily determined by the required distance from the side walls. On the other hand, the active diameter and thus the diameter of the narrowest point of the indentation are essentially freely selectable. In theory, they are limited only by the wafer diameter, but in practice vary greatly, depending on the application; the overall region includes values, for example, between 1 μm and 1 mm, although the active diameters are more often between 2 and 50 μm.

In the illustrated case, at the level of active layer A an annular, high-resistance, or electrically blocking current constriction layer 5 (in the present case, by means of a corresponding oxidation layer, as is known to one skilled in the art) is also provided in active region 3. Alternatively, however, this current constriction layer 5 may also be dispensed with (in which case only a geometric constriction E is present). Since the current constriction layer 5 is provided at the level of constriction E, an oxidation length results for this current constriction layer 5 which is greatly reduced compared to the prior art. In the illustrated example, the side flanks of the n-doped region 2 and of the lower p-doped region 4 of the mesa M formed by the removal of the material, i.e., by provision of the indentation E, have an angle α of approximately 60° relative to the rotational axis of symmetry of the mesa M (which corresponds to the direction of emission of the semiconductor laser). Thus, viewed in relation to the substrate layer plane 1, this results in a comparatively flat progression of these side flanks. Directly adjacent to and on the substrate base 1 and the surface of the first doping region 2, a first side wall metal contact 6a is then provided which has a concentric design over the entire circumference of mesa M in region 2. This side wall metal contact not only completely covers the surface of the first doping region 2 on the side flank of the mesa M, but is also situated on the surface section of the active region 3 facing the first doping region 2, and is thus used in thicknesses up to a few microns on active layer A. A first side wall heat dissipator 7a, in the present case made of gold, is situated on this first side wall metal contact 6a and adjacent thereto. This side wall heat dissipator covers practically the entire surface side of the first side wall metal contact 6a facing away from elements 1, 2, and 3, and due to this design provides optimal dissipation of the heat generated by the semiconductor laser.

The surface of the p-doped region 4 facing away from the substrate base 1 as well as the side flanks of the previously described cylindrical section of this doping region bear a second side wall metal contact 6b. The surface thereof facing away from the p-doped region is enclosed by a second side wall heat dissipator 7b.

As shown, the described geometry results in a greatly reduced oxidation length, and an active diameter (see figure) which extends over approximately one-third of the average cross-sectional diameter of the p-doping region or of the n-doping region.

FIG. 3 thus shows completely novel, and in many respects superior, shaping of monolithic VCSELs, whose manufacture is carried out by means of a technological paradigm change. The novel shape, in itself, improves the component properties as well as the efficiency of component manufacture. In addition, for the first time it allows direct current injection into, and heat dissipation from, the immediate vicinity of the active zone A of the lasers, in particular while optimally bypassing the relatively poor electrically and thermally conductive heterotransitions in the Bragg reflectors 2, 4. Passivation layers between semiconductor and metal which block heat flow (as well as current flow), which have previously been used for side wall coatings intended for cooling, are no longer required.

Practically all of the present commercially used VCSELs based on the InAlGaAs material system contain a thin layer, containing a high proportion of aluminum, within the epitaxial structure which in the prior art has heretofore been used for lateral current constriction by selective oxidation. In the present invention, for the first time use is made of the lateral etching rate differential between this oxidation layer (or also another layer specially provided for this purpose) and the other layers of a VCSEL structure for contouring the mesas according to the invention. This shaping is carried out in a single wet chemical etching step which includes all the epitaxial layers of the VCSEL. In contrast, in the two-step etching known for many years from the prior art, the p- and n-conductive epitaxial layers were structured separately in individual etching steps which usually were not performed in direct succession.

The term “lateral etching rate differential” is understood to mean the difference in the etching rates between the individual epitaxial layers, which results in the formation of geometrically constricted XCSEL profiles during the etching.

The XCSELs are composed of a stack of very thin semiconductor layers having various material compositions. Depending on the layer composition, the semiconductor lattices may be dissolved at different rates using etching solutions. In the vertical direction the individual layers each have only a very slight extension, so that there are no differences in the etching rates, and only an average rate is observed for vertical advancement of the etching solution. In contrast, in the lateral direction the layers are greatly extended, and the etching rate differences may last for a long time, so that different side wall profiles may be formed, depending on the combination of quickly and slowly etching layers. During the etching operation, for the individual component a limited region of the wafer surface is covered by an etching mask (photoresist, for example). During the etching, in the exposed regions the layers are removed one after the other, vertically with respect to the wafer surface, so that as the etching process progresses, at the mask edge the end faces of increasingly deeper layers are exposed to the etching solution. As soon as a layer emerges, it is also attacked in the lateral direction, starting from its end face. As soon as a quickly etching layer is exposed, at that location the dissolution process parallel to the wafer surface advances more quickly than at the locations above and below same, resulting in formation of a notch, i.e., the constriction according to the invention. When a notch is created, the upper/lower adjacent layers are attacked not only from their end face, but also from below/above (see FIG. 3b). Depending on how greatly the etching rates differ from one another, and how long etching is continued after the quickly etching layer(s) appear(s), more or less pronounced notches or constrictions having different depths and flank angles are formed.

Thus, in principle, multiple basic forms or side wall profiles may be “programmed” into the epitaxial layer structure. This epitaxy-controlled production of the XCSEL profiles is carried out efficiently in a single wet or dry chemical etching step which automatically centers all parts of the laser (both mirrors and the active zone therebetween) with respect to one another.

Among other things, perfectly perpendicular walls or wall sections may be produced by wet etching, in that the etching rate of the layers increases in the downward direction to exactly the correct degree, so that the layers which do not take part in the etching process until later may “catch up” with the longer-etched layers at the end of the etching process. Likewise, combinations of multiple notches/constrictions or multiple overhangs in the side wall profile (sections having a negative angle of the side wall between 0 and 90°) may be achieved which in the XCSEL, for example, contribute to even stronger lateral wave guiding, which allows the mode volume to be further reduced in order to make the lasers faster.

The etching rate of the epitaxial layers may be controlled by the composition of the layers, i.e., the concentrations of chemical elements in the compound semiconductor, which in particular for epitaxial growth may be controlled very precisely. This includes the elements of the compound semiconductor, for example Al in AlGaAs, as well as the added dopants such as Si or C, for example. In contrast, in the transport-limited case the thickness of the layers also affects the lateral removal rate of the layers. In addition, any etching behavior is naturally determined by the etchant used, which in the AlGaAs material system, for example, is a mixture of H₂SO₄, H₂O₂, and H₂O.

In conventional mesa-isolated components from the prior art, the side walls represent a potential source of particle losses, which are caused by contact with the corresponding optical or electrical particles, primarily as the result of scattering and surface currents or recombination. For this reason, their influence is eliminated by laterally extended thin insulating diaphragms (made of air or oxide, for example), which, however, are subject to considerable capacitances and which hinder heat flow.

On the other hand, XCSELs according to the invention involve novel functionalization of the side walls. In contrast to conventional concepts, in the present case the side walls are not passivated, and their influence is thus largely eliminated; instead, they have a special shape and assume a new, active role. FIG. 3c shows this distinction in greater detail (left: conventional air post VCSEL; middle: conventional oxide/air diaphragm VCSEL; right: XCSEL according to the invention; Dₐ in each case is the active diameter).

The prior art has the following disadvantages:
Air post VCSEL: hard guiding and large optical and electrical losses due to etched side walls as delimitation of the active zone and the resonator.
Oxide/air diaphragm VCSEL: A thin, laterally extended diaphragm made of an insulating material (for example, an oxide or nitride of the material, or also air, referred to as “oxide constriction” or “oxide diaphragm” for short) is produced. Current constriction and wave guiding occur at the inner edge of this diaphragm, so that the active zone is separated from the side walls by a distance such that its influence is largely eliminated. The particle losses are greatly reduced compared to air post VCSELs by keeping the free charge carriers as well as the laser modes away from the side walls. These lasers are therefore much more efficient than air post VCSELs. However, the laterally extended, thin diaphragms made of insulating material prevent the heat from dissipating from the structure, and also result in considerable parasitic capacitance.
In both cases a constriction is still present although the side walls are not directly coated with line structures in a structured manner.

In contrast, the following applies for the present invention:
Novel, hybrid index guiding by combining a geometric (preferably wedge-shaped) constriction with an oxide constriction. A very short oxide diaphragm, preferably designed as a direct extension of the geometric constriction, results in reduced scattering losses and passivation of the surface of the geometric “guide wedge.”
Due to its large jump in refractive index (for example, semiconductor-air or semiconductor-polymer) and its shape, the geometric constriction provides strong wave guiding, its relative strength being controllable by the depth of the oxide diaphragm. The geometry is preferably wedge-shaped, and differs from the (more or less) straight walls of the air post VCSELs as well as from those of the oxide/air diaphragm VCSELs. For the XCSELs according to the invention, the optical field is kept at a sharply defined distance from the side walls.
At the same time, a side wall profile having overhangs results which may be directly coated in a self-adjusted manner, and which for targeted deposition of conductive materials automatically provides for structuring in the form of an interruption directly at the active layers, i.e., reliably prevents short circuits of p-n transitions.
Because such a side wall profile as described is predefined by the epitaxial layer structure itself, the precision of the structural definition of the side wall coating is increased to levels that are similar to the typical structure sizes of the epitaxial layer structure. The manufacture is very efficient and has a low degree of complexity.
Consequently, the side wall coating is able to surround the optical field in close proximity and to extend at the end up to the central cavity, at which location it supplies current and dissipates heat directly through the side walls. The described hybrid index guiding on the one hand allows the side wall metal plating to extend close to the active regions while bypassing the heterotransitions having poor conductivity, and on the other hand, a sufficiently strong guiding of the field in the narrowest point due to constriction and the oxide layer keeps the optical field at a sufficient distance from these metal surfaces, which otherwise would result in great losses, not only from scattering but also due to induced currents.

FIG. 3d illustrates important aspects of the XCSEL side wall geometry according to the invention, with reference to an example configuration. The approximate detail of the XCSEL (indicated by a dotted line) in the right part of FIG. 3c is shown:

(a) Wedge-shaped “spacer”;
(b) The structural edge together with targeted deposition allows conductive materials in close proximity around the optical field to be guided, separately from above and below, into the immediate vicinity of the active zone;
(c) The short oxide extension causes weaker guiding upstream from the stronger geometric guiding, as a result of which the scattering losses are reduced and the proportion of geometric guiding may be adjusted to the overall guiding (M: side wall metal plating(s), A: active layers; diagrams not to scale).

The active zone may be located above as well as below the narrowest point.

In summary, the invention discloses a novel way of guiding depositable materials laterally, in a targeted manner, to the point directly at the active zone, with the following being preferred:
Spacer: geometric wedge with an optional extension from the insulating diaphragm, and
Side wall profiles with overhangs which may be coated in a self-adjusted manner, and which surround the optical field in the resonator in close, precisely defined proximity and which in turn end in the immediate vicinity of the active layers in a precisely controllable manner.

The resulting X-shaped or diabolo-shaped contour of the lasers according to the invention, as illustrated in FIG. 3 in comparison to the conventional shapes in FIG. 1, combines a large constriction E of the mesa M itself, specifically, directly at the level of the active layers A, with a possible additional current constriction 5 and wave guiding by means of lateral oxidation. The mesa constriction allows minimization of the oxidation length and the associated intrinsic parasitic capacitances, and at the same time allows the scattering losses to be limited as the result of a sufficiently large average distance of the extremely sloped mesa walls (α=approximately 60° with respect to vertical) from the optical field in the resonator. In addition, the shape according to the invention improves not only the potential modulation speed of the VCSELs due to reduction of parasitics, but also the heat loss discharge within the structure, for which the oxide layer 5 represents an impediment. Improved discharge of heat keeps the operating temperature at a lower level, which in turn has a direct effect on the achievable modulation speeds. However, cooler lasers not only have higher speed, but, among other things, also longer service lives and higher power output.

The shape according to the invention also opens the way for a significantly more advanced technology. Besides the advantages strictly from the standpoint of cost-effectiveness of manufacturing, the shape allows the integration of optional additional elements which previously were not feasible, as well as increased precision. Both of these factors result in substantial improvements in performance of the components, in particular with regard to thermal management and all of the associated performance parameters of these lasers, which generally are thermally limited and subject to power loss.

In the solitary XCSEL according to the invention shown in FIG. 3a, the additional elements are the electrical and thermal side wall contacts and heat dissipators, which, precisely structured, are each able to extend directly to the active layers within the cavity and, without a passivating intermediate layer which blocks the heat flow, may be brought in direct contact with the “end faces” of the epitaxial layers on the side walls. These elements have no corresponding counterparts in the conventional VCSELs according to FIG. 1, and the side wall profiles of the XCSELs are used as a shadow mask (for vacuum deposition, by vaporizing or sputtering) or as a lithography mask (for galvanic deposition) in manufacturing the XCSELs.

In particular, by making use of the mesa overhangs the p contact 6b as well as the n contact 6a may be produced as shadow masks with high precision and in a completely self-adjusted manner without requiring a separate lithography step. As a further feature according to the invention, the n contact 6a is also (or exclusively) formed on the mesa flanks. It may extend on the side wall all the way to the inner cavity E, thus bypassing the relatively high-resistance heterotransitions of the Bragg reflector 2 and allowing efficient current injection on the side walls in the immediate vicinity of the active zone A (“intracavity side wall injection”). This approach is particularly attractive when VCSELs having an elongated inner cavity are used, in which a larger contact surface area on semiconductor layers having a smaller band gap for good ohmic contact is available. These layers may be partially highly doped in regions of low field intensity. In addition, the alloying of the n contact material causes degenerate doping of the side walls. As a result, during the epitaxial growth the Bragg reflectors 2, 4 may then be optimized even with regard to reduced free charge carrier scattering and increased reflectivity, since they are no longer absolutely needed, and to the full extent, for charge carrier injection. Possible shortening of the Bragg reflectors once again improves the cooling of the active layers.

The p contact 6b and n contact 6a may be produced as follows (also see FIG. 3e):
1. Perpendicular deposition of the metal system (in the present case, the metal plating sequence for p contacts, for example Ti:Pt:Au) appropriate for the polarity of the upper XCSEL portion facing away from the substrate.
2. Oblique deposition, with rotation, of the metal system (in the present case, the metal plating sequence for n contacts, for example Ge:Au:Ni:Au) appropriate for the polarity of the lower XCSEL portion on the substrate side.

Example A (A in FIG. 3e): Without a flat cylinder in the upper portion, and therefore with only a topmost edge for definition of the lower contact.

Example B (B in FIG. 3e): Having a short geometric constriction and almost completely coated side walls, also in the upper portion, which has slightly negatively sloped side walls. In this case, the lower of the two edges of the upper XCSEL portion acts for defining the contact end situated at the active zone.

Example C(C in FIG. 3e): The upper portion has slightly positively sloped side walls, so that ohmic contacts for lateral current injection are also produced on these walls.

It is critical that the desired type of metal comes to rest on a sufficient contact surface area having the respective polarity. The overhangs or constrictions in the XCSEL profiles allow this without the active regions and surface areas of the respective other polarity being covered with photoresist, using lithography steps. Ohmic or blocking side wall contacts result, depending on which metals are deposited on the p- and n-doped regions.

For vacuum deposition of the contact metals, the wafer is mounted on a tilting device which allows the angle of orientation of the wafer surface relative to the source as well as the angle of rotation to be adjusted. If the upper portion is p-doped, for example, in a first step the metals for a p contact are deposited while the wafer plane is situated at an angle of 90° with respect to the source, so that the metals impinge on the wafer surface exactly perpendicularly. All of the surfaces visible from the top are coated with p-metal. The metal layer situated on the substrate has an opening which begins precisely vertically beneath the most outwardly projecting edge of the XCSEL profile. For the coating with the n-metal for low-resistance contacting of the lower n mesa section facing the substrate, the wafer is then tilted precisely so that the inner edge of these n-metal layers results directly at the active zone. The position of the inner edge results from the projection on the lower side wall of one of the protruding edges of the XCSEL profile at the selected angle.

The upper XCSEL portion facing away from the substrate may or may not contain the previously described flat cylinder, depending on the embodiment. Thus, either one (see Example A) or multiple (Examples B, C) edges result, which at various tilting angles may be used as shadow masks for defining the contact edges. The n-metal also comes to rest on the XCSELs at the top, and on the substrate at the bottom on the p-metal already deposited at that location, so that in these regions it is not in contact with the semiconductor and therefore has no electrical effect.

If the upper portion is designed in such a way that its flanks have a slightly negative angle as in Example B, for oblique coating the n-metal is deposited on the flanks of the p portion, resulting in an electrically blocking contact via which heat may be discharged. Providing a space charge zone beneath the contact surface also results in a field-specified current constriction of the charge carriers (in the present case, holes), which in this case are injected via the top side of the mesa.

In Example C the upper portion has slightly positively sloped flanks, which during the first, perpendicular coating are then covered with the metal which forms ohmic contact having the polarity of the upper portion of the mesa. Thus, in this embodiment there is the possibility for lateral current injection close to the cavity, via the side walls, for both types of charge carriers.

This method functions reliably in practice. However, process sequences are also possible in which, before any etching, a metal contact is produced for the upper mesa using a standard liftoff method. In that case, in addition to the side walls the entire substrate surface may be coated with the metal which establishes an ohmic contact for the substrate. This is meaningful in particular when the substrate is not subsequently removed and is also intended to be used for current injection.

The above-mentioned possible shortening of the Bragg reflectors may be carried out as follows:
The Bragg reflectors are composed of approximately 25 to 40 pairs of semiconductor layers above and below the active zone, i.e., the cavity, which in each case have a total thickness of a few microns (approximately 3-6 μm). This many layer pairs are generally necessary in order to obtain the desired high overall reflectivity from the individual reflectivities between the layers. However, the large overall thickness of these layer stacks, and in particular the plurality of interfaces between the layers, hinder current flow and heat flow. The overall stacks become sufficiently low-resistant by gradual transitions between the layers and partial high doping.
However, these measures reduce the individual reflectivities between the layers and increase the absorption, i.e., the optical losses in the mirror. Thus, on the whole, for achieving a required overall reflectivity it is generally necessary to have a higher number of mirror pairs than is the case for a layer stack, in which the current is laterally injected and then flows primarily laterally in only a few layers close to the cavity; i.e., it is not necessary to ensure low resistance for perpendicular current flow. Such a Bragg reflector may be undoped for the most part, thus increasing the efficiency of the laser due to lower absorption. In addition, only abrupt boundaries are possible instead of smooth transitions between the layers.
The index contrast between the reflector layers may be increased, since it is no longer necessary to take band discontinuities into account as long as the material is transparent for the operating wavelength. In the AlGaAs material system this is equivalent to stronger binary portions of the layers, which greatly improves the thermal conductivity of the material due to the fact that it decreases markedly with increasing ternary character. The thermal conductivities are approximately as follows:
   0.5 W/cm/K for GaAs and 0.8 W/cm/K for AlAs, but only 0.1 W/cm/K for Al_{0.5}Ga_{0.5}As.
Lastly, lower absorption and higher individual reflectivities not only result in increased efficiency, but also result in the Bragg reflectors achieving the required high overall reflectivity with fewer mirror pairs, i.e., with a lower overall thickness. As the result of a lower “installation height” of the two mirrors, the path for the heat dissipation in the vertical direction is also shorter, and the cooling of the active layers is further improved.
Therefore, reduced mode volume in the longitudinal (vertical) direction is another aspect. The circulation time in the resonator is thus shortened, which likewise contributes to higher modulation speeds.
If high Al fractions are present in the layers in (essentially) binary DBRs, these layers are optionally laterally oxidized as well, thus forming a funnel provided by multiple stacked oxide diaphragms, as shown in the left side of FIG. 3f. Thus, the charge carriers which are injected into the side walls at a farther distance from the cavity are likewise able to flow to the active zone in a funnel shape, which contributes to more uniform lateral current distribution at the level of the active layers, thus counteracting current increases at the aperture edge and allowing more uniform pumping of the active surface, in particular at higher currents. Due to the laterally outwardly extending side walls, this design of the XCSEL shape also tolerates oxidation depths in the DBR layers which are laterally extended farther than the oxide diaphragm at the level of the active layers.
On the other hand, oxidation of reflector layers remote from the cavity may also be prevented by closing their end faces, as shown in the right side of FIG. 3f, by metal plating prior to the oxidation process.

The XCSELs according to the invention allow lateral current injection via sections of the side walls without depending on thin, laterally extended current supply layers. The profile which tapers toward the active zone, together with placement of the contacts on the side walls, greatly shortens the current flow paths compared to previous approaches for intracavity contacts.

At the same time, by alloying the contacts very high doping of the side walls may be achieved, which may be located so close to the edge of the current aperture on sections near the cavity that the depth of penetration of the contacts may practically bridge the remaining distance, resulting in low serial resistances.

In contrast to lateral continuous highly doped regions, however, this does not result in increased absorption, since the doping is less at locations where the optical field is guided in the resonator. The depth of penetration of the alloy contact should be such that the periodic structure of the layer inside the active diameter is not destroyed.

This process corresponds to subsequent doping of regions beneath the side wall surface, so that, due to the subsequent processing, a laterally varying doping profile results in addition to the longitudinal varying epitaxial doping profile. Alternatively, the XCSELs according to the invention offer the option of producing a laterally varying doping profile by overgrowth in a second MBE step in which highly doped semiconductor material is deposited on the side walls in a targeted manner.

Thus, the optical path and the current path may run separately, at least in places, thus reducing disadvantageous effects such as free charge carrier absorption and line broadening due to modulation.

The greatly increased precision of the structural definition according to the invention without manual adjustment steps makes the manufacture cost-effective by eliminating sources of error, and opens the way for further miniaturization of the components for increasing the modulation rates and integration densities. By using the structure according to the invention, entire process steps may be dispensed with, or replaced by steps which may be easily automated in a production environment. In particular, essentially eliminating time-consuming (usually manual) contact lithography significantly shortens the throughput times for the wafers, saves on personnel, and conserves the costly VCSEL wafer material, since less is used in the manufacture.

For example, in conventional VCSEL design, for defining the geometries a lithography step is necessary for each individual structural element. In contrast, for the XCSEL according to the invention, in a suitable production facility (after installation of remote-controllable tilting actuators) both electrical contacts 6a, 6b (p- and n-side) as well as vapor-deposited n-side heat sinks 7a, 7b may be sequentially produced without breaking vacuum, i.e., practically in a single step. The accompanying reduction in development times is relevant in particular for the increasingly important capability for rapid adaptation of existing base designs to specific customer demands. In addition, contact lithography, in which the wafer surface is pressed against a glass disk, represents a significant stress in particular for VCSEL wafers due to their pronounced surface topography. Largely eliminating such stress-producing processes therefore also increases the yield, i.e., reduces the proportion of previously damaged components which must be sorted out using burn-in tests.

Rough Exemplary Comparison of Process Times (Lithography, Evaporation, evacuation, LO (Lift-Off):

### VCSEL:

p contact: litho. 1 h; evap. 4-6 evac.+0.5 h process; LO 0.5 h
n contact: litho. 1 h; evap. 4-6 evac.+0.5 h process; LO 0.5 h
(Vapor-deposited heat sink: litho. 1 h; evap. 4-6 h evac.+0.5 h process; LO 0.5 h)
   However, this heat sink is hypothetical, since it is practically ineffective due to the excessively large distance from the active zone.
      Total=18-24 h (12-16 h without heat sink)

### XCSEL According to the Invention:

| | | |
|---|---|---|
| p contact: | evap. 4-6 h evac. | +0.5 h process; |
| n contact: | | +0.5 h process; |
| Vapor-deposited | | +0.5 h process |
| heat sink: | | |
| Total: | 5.5-7.5 h (5-7 h without heat sink) | |

Even without heat sink 7a, 7b, which for the XCSEL according to the invention is extremely effective, in contrast to the VCSEL over one-half of the process time is saved, compared to the case with heat sink 7a, 7b, in which over two-thirds of the process time is saved. Naturally, the energy expenditure decreases accordingly.

A further advantage of the XCSELs according to the invention is the precise knowledge of the oxidation length. In conventional wet-etched VCSELs (FIG. 1(a)), the starting point of the oxidation is in the curvature of the flatly extending p mesa. Due to the surface gradient in this region, even small fluctuations in the etching depth have a drastic effect on the outer diameter of the oxidation layer, and therefore on the oxidation length required for a given target diameter of the current aperture. For many present applications, however, the active diameter of the lasers must be known with an accuracy in the submicron range. If this diameter is not met with sufficient accuracy in the oxidation process, there is the risk of loss of the entire wafer, since it is not possible to subsequently correct an oxidation operation once it has been carried out. Even if known, in situ control in the oxidation chamber through which steam flows is not used in production facilities, most likely primarily because of disturbance of the laminar gas flow and of the temperature distribution caused by the optical systems, which would impair the homogeneity of the oxidation rate over the wafer surface. Furthermore, due to the flat extension of the mesa, the outer diameter of the oxidation layer cannot be measured without destruction or with sufficient accuracy. At the present time, one common solution to this general problem is to implement the p-side mesa using a dry etching process, resulting in structures as illustrated in FIG. 1(b). A precisely adjusted dry etching process results in perpendicular mesa walls, so that the outer diameter is known with certainty. However, the outlay for equipment is several times higher than for wet etching, and the semiconductor surface is damaged by ions which strike it.

For the XCSEL according to the invention (FIG. 3), the oxidation begins exactly in the narrowest point E of the mesa. The starting diameter is sharply defined despite the use of an economical wet etching process. The starting diameter results from the vertical and lateral etching rates of the epitaxial layers and their individual positions in the vertical layer structure. In the simplest case wet etching, the same as dry etching, is a timed process. For dry etching, however, the etching rate is usually better controlled under laboratory conditions due to the equipment, which from the outset is much more complicated. However, wet etching may also be precisely controlled under production conditions (composition, temperature, agitation, age of the etchant, etc.) without losing its cost advantage over dry etching. In contrast to dry etching, in which the etching depth may be observed in situ only by use of complex laser optics, for wet etching it is even possible to carry out visual in situ control using suitable lenses, for which in the case of XCSELs on account of the geometry according to the invention quite accurate conclusions may be drawn concerning the starting diameter of the oxidation; in this case, as described, small variations in the etching depth also have comparatively little effect on the starting diameter. Since for the XCSEL according to the invention the oxidation layer 5 is situated exactly in the narrowest point of the mesa, the starting diameter may be accurately verified once again before the oxidation. After oxidation is complete, the starting and ending points of the oxidized region may be easily identified by imaging with a CCD camera, since in the top view they do not coincide with any other edge of the structure, as is the case for dry-etched mesas.

It is also apparent from FIG. 3 that the contour of the XCSELs according to the invention offers the possibility of positioning thick heat dissipators 7a, 7b, applied physically (vapor deposition) and/or galvanically, with such precision that, similarly as for the n contact 6a, they are able to extend to the immediate vicinity of active zone A without an underlying passivation layer which blocks the heat flow. For this purpose, the specialized laser geometry is used as a built-in lithography mask in order to provide the exposed active layers with a protective enclosure using a collar made of a suitable photoresist. The shape of the photoresist collar may be adjusted very accurately by adapting the shape of the X mesa, i.e., by the selection of the ratio of inclined and vertically extending portions of the mesa wall (in this regard, see the p mesa in FIG. 3: in the example shown, approximately the lower two-thirds of the p mesa wall are inclined, and the upper third, vertical), and via the photoresist thickness and the exposure dose. Thus, no external lithography mask is necessary. In addition, this process is carried out in a self-adjusted and “contact-free” manner, which, as described, conserves material.

The heat dissipators 7a, 7b implemented in this manner cool active region A with an efficiency heretofore unachievable, since they collect the heat inside the resonator directly at the locations where cooling directly influences the intrinsic variables which specify the dynamics. For the most part, the heat flows laterally within the cavity E in the direction of increasing thermal conductivity of the epitaxial layer structure, to the tip of the metal heat dissipators. The path to that location may be extremely short due to the particular mesa shape in conjunction with greatly reduced oxidation lengths, and does not have to initially lead in the vertical direction via heterobarriers with their reduced thermal conductivity. Depending on the dimensions of the XCSEL, the tip of these “cooling probes” may extend to the side wall of the inner cavity, and may thus be situated only a few microns from the edge of the current aperture. Nevertheless, the metal is in direct contact with the semiconductor, without blocking intermediate passivation layers located on the side walls, which greatly increases the heat exchange beyond this interface.

For example, data transmission VCSELs generally achieve the desired high modulation speeds, as well as flat progressions of the transmission functions with sufficient signal deviation, only at high pump flows combined with good discharge of the heat loss. As mentioned, direct dissipation of the heat loss from the active zone decreases the operating temperature directly at locations where temperature-dependent variables have a direct influence on the dynamic properties of the lasers. The technology according to the invention allows sufficiently thick heat dissipators 7 to be brought extremely close to the active zone without in turn creating dominating parasitic capacitances, which would eliminate the dynamic advantage achieved by direct cooling of the inner electro-optical processes due to the additional introduction of parasitic extrinsic capacitances. In conventional technology, sufficiently thick metal layers which are located close enough to the active zone to be thermally effective always included the incorporation of large geometric capacitances, which greatly impair the high-frequency modulation capability. In contrast, the XCSELs according to the invention allow the implementation of cooling structures which cause no capacitances which impair the modulation capability, which has been confirmed in data transmission tests.

Thus, in particular the following applies for the surface-emitting semiconductor lasers compared to the prior art:
1) Conventional wet chemical etched VCSELs according to the prior art (FIG. 1(a)):
   Average level of manufacturing effort, poorest performance.
   Long process times and numerous process steps.
   Each element must be manually adjusted individually; required tolerances prevent efficient miniaturization.
   Large, poorly defined oxidation lengths; poor reproducibility of active diameters; large parasitic capacitances and low modulation speeds.
   No easily integratable or efficient cooling structures.
2) Conventional dry-etched VCSELs (see FIG. 1(b)):
   High costs, improved performance compared to 1).
   Expensive dry etching, therefore slightly shorter and better defined oxidation length.
   At best, only the p contact is self-adjusted with respect to the p mesa having the active zone.
   Other disadvantages as listed under 1).
3) XCSELs according to the invention (FIG. 3):
   Lowest costs.
   Best performance.
   Completely self-adjusted and only wet-chemically etched.
   Reduced parasitic capacitances, decreased scattering losses, and superior thermal management.

FIG. 4 shows a detail of a system of a plurality of surface-emitting semiconductor lasers according to the invention, having the previously described design according to the invention. The individual semiconductor lasers (only one of which is shown here) are situated in the form of a two-dimensional matrix on or at a substrate base having a plurality of substrate base sections 1 (associated with the individual lasers), each having a three-dimensional shape as shown in FIG. 4.

The basic design of the individual surface-emitting semiconductor laser (having elements 1 through 7) shown in FIG. 4 is the same as that described for FIG. 3. In the present case, however, the substrate 1 or the substrate base section 1 has a spatial design in the form of a polymer layer, in the present case a passivating layer (such as polyimide or BCB, for example), in such a way that in the region of its constriction E, the mesa M of the illustrated semiconductor laser is bordered by the illustrated substrate base section 1 in a positive-fit manner. This (supporting) substrate base section should not be confused with the semiconductor substrate which is removed here (see the description of FIG. 4b below) except for optionally present residual structures 13a, 13b. This results in a mounting in which the illustrated semiconductor laser element is bordered in a free-floating manner without the need for supporting substrate sections or structures on its top or bottom sides (i.e., the surfaces of the first and second doping regions 2, 4 facing away from the active region 3). However, it is also possible, for example (shown here in two variations 13a, 13b in dashed lines), to provide corresponding support structures 13a, 13b made of another substrate material (in the present case, a semiconductor material such as Si, for example) on the outer side of the n-doped region 2 facing away from the active region 3, or to correspondingly support said surface in partial regions using remaining substrate sections made of a semiconductor material. A detailed analysis of the illustrated case shows that in the present example, the substrate base section 1, together with the first side wall heat dissipator 7a and together with the first side wall metal contact 6a, is shaped in such a way that the described positive-fit bordering of the semiconductor laser element or its mesa M is provided at the level of the constriction E.

According to the invention, however, the substrate base section 1 and the side wall metal contact/side wall heat dissipators 6a, 7a are shaped not only for bordering the semiconductor laser; in the region of the border of the semiconductor laser element, or concentrically around same, they also form a mechanical guide structure F due to their illustrated shape. This guide structure is formed by providing a tub-shaped depression in elements 1, 6, 7 around the laser border. This depression is designed in such a way that an optical element, in the present case a fiber 8 of a glass fiber bundle, may be inserted into the mechanical guide structure F in a self-centering or self-centered manner (viewed in relation to the laser), and may be fixed at that location using an appropriate transparent adhesive layer, for example. After the fiber 8 is fixed, it is not only centered with respect to the laser, but at its end face surface facing the laser it is also separated at a distance from the emission side of the laser (surface of the n-doped section, in the present case characterized by the photon radiation energy h·ν). Tilting of the fiber in the guide structure (angle error) which appears to be possible is prevented in that this is actually a matrix of elements which are connected to one another with sufficient rigidity. Thus, the array of optical elements, in a manner of speaking, stands on many “legs” and cannot tilt. However, the fiber guide may also have other geometries, in particular steep walls which are thus similar to the through-contacting mesa (the fiber guide may also be dry-etched, although wet chemical etching is preferred for cost reasons). In addition, the flat underside of an optical element may also be flatly mounted, and at the same time, with respect to the orientation in the plane (x-y plane, i.e., perpendicular to the plane of the drawing and to the direction of the laser emission) an angle error (tilting) may also be avoided, even with a single component.

Thus, the mechanical guide structure F results in an interspace Z between the semiconductor laser or its mesa M and the end-face end of the optical element 8. This interspace may be filled with a transparent material for optical coupling. Alternatively, however, using suitable inlet and outlet elements, for example, the guide structure F may be designed in such a way that a transparent gaseous or liquid medium (in the simplest case, N or deionized water) may be led through the intermediate region Z, thus providing for discharge of the generated heat and corresponding optical coupling.

Alternatively or additionally, it is possible to provide channels 14 in the optical element (in the present case, in fiber 8) through which a cooling medium (cooling liquid or gas) may flow into the interspace Z in a targeted manner (in this case, the channels introduced into the fiber 8 run parallel to the axis of symmetry or longitudinal axis of the fiber, although the channels may also run longitudinally between the individual multimode fibers in the fiber bundle. In that case the cooling medium impinges with a lateral displacement relative to the lasers, which leaves room for the described adjustment of the index of refraction. A circuit may also be produced; i.e., various partial quantities of the channels are operated as inlets and outlets).

Thus, the XCSEL according to the invention in FIG. 4 is bordered only by the metal layers of the side wall contact and heat dissipator on the substrate side (reference numeral 7a) and a polymer layer such as polyimide or BCB (reference numeral 1). As further explained in FIG. 4b, before its removal the semiconductor substrate 13 (corresponding to the substrate 1 in FIG. 3) is located on top in FIG. 4 for the case of flip chip integration (see residues 13a, 13b). Thus, the XCSEL from FIG. 3 is upside down in FIG. 4. However, the polymer layer 1 in FIG. 4 is not present in FIG. 3, since only the actual lasers are shown here, before any packaging takes place.

In addition, in FIG. 4 the semiconductor substrate 13 has been removed except for the optional residues 13a, 13b, in particular for exposing the mechanical guides F for optical elements and also because the semiconductor substrate is not transparent for frequently used wavelengths. After the substrate is removed, a free-standing structure 1, 7a having sufficient stability remains, as illustrated in FIG. 4. For industrial applications, the interspace is usually filled with an underfill UD for additional stability.

FIG. 4b shows an intermediate step which illustrates the production of the XCSEL from FIG. 4. FIG. 4b illustrates the manner in which the wafer surface is further shaped beyond the actual XCSEL in FIG. 3 in order to produce additional profiles, which are then shaped by the subsequently applied layers (side wall contact and heat dissipators, followed by the polymer layer, not shown here). After the flip chip soldering the substrate 13 points upward and is removed, so that in each case the counterparts of the profiles initially etched into the substrate come to the surface in these layers. For mechanical guiding for the optical coupling, the desired shape, namely, the “negative,” so to speak, of the original raised area in the substrate results first. On the other hand, for the through-contacting mesa the resulting shape in the applied layers is likewise hollowed out (completely or partially) when the substrate is removed, but this plays no functional role.

The procedure may be roughly subdivided as follows:
1. Production of three-dimensional profiles in the wafer surface 13
2. Coating/shaping of these profiles
3. (Flip chip) soldering, with the coated epitaxial side upside down on a carrier substrate
4. Removal of the XCSEL substrate 13, thus exposing the guide structures (The layers, which otherwise are free-standing, may be mechanically stabilized in the customary manner by filling the free space between the soldered connections with an underfill UD.)

As shown in the lower left part of FIG. 4, the semiconductor laser or its mesa M is contacted, via the p-side side wall metal contact 6b and the side wall heat dissipator 7b situated thereon, with a flip chip support 12 having electrical feed lines and an optionally integrated electronics system (in the present case, a CMOS chip, for example) by embedding into a soldered connection or solder ball 9 (also referred to below as a bond pad 9). This is achieved in that the approximately ellipsoidal soldered connection 9 surrounds elements 4, 6b, and 7b.

As further shown in FIG. 4, electrical through contacting 10 is provided in the illustrated substrate base section 1 at a lateral distance from the border region E for the laser, or the mechanical guide structure F for the glass fiber bundle 8. As described in greater detail below, in the present case this through contacting 10 is provided in the form of a through-contacting mesa, i.e., a prominence of the side wall metal contact 6a on the n side, the associated side wall heat dissipator 7a, and the substrate base section 1 toward the CMOS chip 12. The through-contacting mesa is denoted by reference character DM. As described in greater detail below, the elevated section, i.e., the protruding section of the through-contacting mesa DM, is integrated into an essentially ellipsoidal through-contacting soldered connection 11 (also referred to below as through-contacting bond pad 11) or is enclosed by the latter (this connection is formed from a soldering material, the same as connection 9). As shown in FIG. 4, the through-contacting soldered connection 11 is then contacted with the CMOS chip 12.

After the above-described processing, the electrical through contacting 10, viewed from the direction of the emission side (n-side) toward the p side, has the following layer sequence, in which the individual layers are each provided in the form of superposed, adjacent protrusions or prominences (facing the p side): metal plating contact layer 6a′, heat dissipation layer 7a′, and heat dissipator 7b′ in direct contact with bond pad 11. The stabilizing substrate section 1′ is situated in the flank region of the prominence, between layer 7a′ and layer 7b′. In this case element 7b′ is primarily a non-flat bond pad, which naturally also contributes to heat dissipation, but not as strongly due to the fact that it is separated from the laser by a larger cooled surface.

FIG. 4 shows in a schematic cross section an individual cell of a flip chip-integrated XCSEL array according to the present invention, having an enclosure 7b of the anode side (p side) with heat-dissipating metal which merges directly with the soldered connection 9, having a side wall heat dissipator 7a close to the cavity (situated in region E) and led out on the optically bound side, having an integrated fiber guide F with an optional inlet and/or outlet (for example, also in the form of a circuit) 14 for cooling gas and, as described below, having adjustment of the index of refraction in the interspace Z, and having through contacting 10, DM according to the invention for the cathode potential (n side).

FIG. 5 shows an enlarged view from FIG. 4, which is used to illustrate the heat flow paths (shown in dashed lines) in the flip chip-integrated XCSEL design according to the invention. It is seen that heat generated by the semiconductor laser element is dissipated via the soldered connection 9 as well as the support structure 1, 6a, 7a, having side wall heat dissipator 7a, situated in indentation region E. The extremely short path from the current aperture edge in active region 3 to the tip of the n-side cooling probes or side wall heat dissipator 7a, and then to the optical side, is particularly effective in the present case.

FIG. 4 shows the further design of the XCSEL according to the invention for the specialized application of the flip chip integration of VCSEL arrays having drive electronics. In the present case, the previously described paradigm change in manufacture of the component results in a number of additional significant innovations. In the conventional approach which has become established over the past ten years, the pronounced vertical profiles on the wafer surface, which are inherent in such VCSELs (FIG. 1), were considered to be a “necessary evil,” and therefore efforts were made to keep them as small as possible and to re-planarize the unavoidable remaining topographies after they were formed. One example of such a conventional comprehensive planarization via multiple additional metal plating and passivation levels is illustrated in FIG. 2. Compared to manufacture of the actual laser, planarization and embedding in flip chip-contactable structures require a disproportionately high level of processing effort. In this regard, for example each organic layer is individually baked for several hours at temperatures up to 350° C. In addition, the technology used is susceptible to process fluctuations and depends on diligent adjustment by the operator, which makes it less suitable for a production environment.

The technology on which the XCSELs according to the invention are based follows a different line of thought, in that the technology is purposely used to model the wafer topography. In this case the processing begins with three-dimensional shaping of the wafer surface in a sequence of wet etching processes. Thus, at the start of the processing, pronounced vertical profiles having a complex structure are provided in the wafer material, portions of which later shape new elements which could not be feasibly implemented heretofore. The technology of VCSEL which emits on the substrate side and which is remote from the substrate, which has dominated in the flip chip integration of VCSEL arrays with electronics systems on account of existing standards, has received a boost in development due to the introduction of XCSELs. Thus, for the first time it is possible for the heat loss, which as described is extracted from the immediate vicinity of the active zone by the side wall heat dissipators 7, to be conducted directly on the optically bound back side of the lasers with thermal bridging of the cathode-side Bragg reflector 2, as shown in FIG. 4. This side may be cooled particularly well due to the fact that it faces away from the electrically connected side, which is additionally heated by the heat-producing drive electronics.

This is possible due to the elimination of continuous epitaxial layers, which heretofore provided lateral current transport between the laterally displaced soldered contact and the VCSEL on the emission side, and as part of the optical path (see FIG. 2), which heretofore provided lateral current transport as a cathode-side contact layer, and which as part of the optical path also was responsible for additional absorption losses. In the XCSEL according to the invention, the cathode-side electrical contacting, exactly in the same way as for thermal contacting, occurs primarily on the sloping flanks of the lasers, so that there is no need for current supply layers which extend laterally beyond the largest diameter of the VCSEL mesa, and which would hinder the heat flow toward the optically bound side.

As a further aspect according to the invention, the novel heat dissipators 7 may be directly formed into integrated mechanical guides F for the self-adjusted optical binding to glass fibers or microlens arrays on the back side. The production of these guides is likewise possible in a self-adjusted manner in the novel technology, without the need for manually adjusted backlight lithography, for example. The fiber guides F are structured on the wafer plane from the front side of the wafer in combination with the surface etching for the lasers, which is carried out anyway. Thus, very little additional effort results. The guides are exposed when the substrate is removed from the back side (emission side), and then guarantee problem-free docking to the lasers which is precisely adjusted, for example, for each individual fiber of a suitable fiber bundle. For this purpose the soldered-on XCSEL array, as customary, is first mechanically stabilized by packing with a suitable underfill. The advantage of these fiber guides for the overall system of the parallel-optical data connection lies in the reproducible and uniform coupling efficiencies for all laser-glass fiber/lens pairs.

In addition, costly external adjustment structures such as additional manufactured precisely fitting pins on the control boards, as well as personnel- and time-intensive alignment of the system components with one another, are unnecessary. For an acceptable lateral displacement of ±15 μm maximum for injection into multimode fibers having a core diameter of 50 μm, the requirements for dimensional accuracy of external adjustment structures would far exceed the standard production tolerances of printed circuit boards in the range of ±50-100 μm, thus increasing the costs. As a result, it is now possible not only to globally adjust fiber bundles or microlens arrays in their entirety to form the VCSEL array in conventional transmitter modules, but also to simultaneously handle the individual paired alignment of each laser of a VCSEL array for the corresponding element of an array made of fibers or lenses, for example, similar to the manner in which all contacts are simultaneously produced in a single reflow soldering operation on the electrically connected side and aligned by automatic floating. The embodiment of the XCSELs shown in FIG. 4 includes directly integrated adjustment devices F in each individual component, which extends simultaneous processing of identical elements as an advantage of the array technology to the individual alignment and coupling of optical elements to the lasers.

The integrated guide structures F result in a very precisely known and in particular also stable vertical (axial) distance between the laser extraction facet and the end face of the fiber. The interspace Z between the VCSEL and the fiber, identifiable in FIG. 4, may then be filled with material for adjusting the index of refraction. This may be an adhesive which fixes the fibers and at the same time is transparent for the operating wavelength. In the ideal case, the index of refraction thereof is adjusted to the width of the interspace. Back-reflections from the fiber end face into the laser, which may impair the dynamic behavior of the components, are thus essentially prevented. In another embodiment, the adhesive is applied only locally to the support points of the fibers 8. The cavity Z which remains may then be used for further cooling of the VCSELs. Instead of two-dimensional bundles of regular multimode fibers, for this purpose it is even conceivable to use bundles of suitable photonic crystal fibers (holey fibers), wherein the continuous longitudinal openings in such fibers, when they are of sufficient size, may be used for the targeted inflow of a gaseous cooling medium, for example cooled N₂. In a simpler, and, if possible, more economical case, openings 14 extending between the individual multimode fibers in the fiber bundle may be used for the inflow. The cooling medium is then impinged on with a slightly lateral displacement with respect to the active components, which leaves room for the described adjustment of the index of refraction.

Likewise in the course of the initial three-dimensional shaping of the wafer surface by wet chemical etching, with a similar efficiency as for the fiber guides, mesas DM for the cathode-side through contacting 10 of the flip chip contact are also formed from metal. These mesas replace the previously generally used, but very problematic, technique of polymer blind hole electroplating. This conventional technique requires multiple contact lithography steps. In the same manner, the alternative use of dummy VCSEL mesas also requires separate treatment thereof in deposition processes involving additional contact lithography steps. In addition, even minor lithography problems frequently prevent homogeneous and reproducible electroplating in all polymer openings distributed over the entire wafer, also during the diffusion processes in the metal plating which take place during the mandatory high-temperature treatment of the polymer, with subsequent oxidation of unknown species at the exposed surface. In principle, a polymer blind hole is also a geometry that is poorly sealed by electroplating. Since it is not possible to deposit on the inert polymer by electroplating, in general no close bond is formed between the metal column and the flanks of the opening which are made of polymer and have a height of several μm. After filling with metal, a fissured surface, not an actually flat closure, thus remains. However, well-sealed transitions between the metal-plated levels are very desirable, in particular for reflow soldering which is used for flip chip bonding.

In contrast, the technology according to the invention which is based on the purposeful wafer surface modeling once again has manufacturing-specific advantages as well as a function which is superior to the conventional structures described above. A column 1′ etched in the semiconductor material 1 during the initial wafer surface modeling (approximately 20 μm high with a plateau 5 μm wide; also see FIG. 4b) is easily uniformly coated as well in each metal-plating process in the further course of processing (sections 6a′, 7a′ of elements 6a, 7a). No further precautions are necessary for this purpose; the intended structures 6a′, 7a′ result due to the mere existence of the columns 1′ themselves. After the XCSELs are completely processed, together with the columns 1′, 6a′, 7a′ which now have been metal-plated multiple times, the XCSELs are poured into a single layer of unstructured polymers (element 1 in FIG. 4). The subsequent baking is carried out with complete exclusion of air on the wafer surface as the result of the polymer. Lastly, the polymer layer is uniformly back-etched in a brief plasma step. The anodes 4 of the XCSELs according to the invention which are enclosed with metal, as well as the through contactings 10 on the cathode side, are then free, thus forming the surface profiles indicated in FIG. 4 due to the contours on the wafer surface as well as the flow characteristics of the spin-coated polymer. The mesa made of semiconductor material, which originally shapes the through contacting, is etched out of the depression formed by the metal layers during final removal of the substrate in the flip chip-soldered state.

This type of through contacting 10 entirely dispenses with a separate metallic filling. The transitions between the involved structural elements are geometrically fluid, and do not have the sharp angles as is the case for the conventional blind hole structure. In addition, all materials used adhere tightly to one another. This results in a smooth surface which is easily sealed off by a bond pad. Unlike the flat bond pads, which in other respects are fairly common, this through contacting forms a prominence DM which is enclosed by the solder ball 11, thus improving the stability of the soldered connection.

Here as well, the structural discontinuities are reduced compared to the conventional connection according to the prior art, since the ascending flanks of the solder bridge (see element 11 in FIG. 4) are able to contact likewise ascending flanks of the bond pad (not explicitly visible in FIG. 4). This results in force flows within the structure which are comparatively spatially balanced without significant local increases and sudden changes in direction of impinging forces. This prolongs the module service lives, since in service life tests (repeated run-throughs of temperature cycles), locations having such structural discontinuities have typically been shown to be the starting point for the production of cracks. Furthermore, in addition to the customary contact due to interdiffusion of the materials during soldering, the soldered connection thus produced also has a positive-fit component due to the fact that the solder ball encloses the bond pad bump. This makes the resulting soldered connection even more stable than in the conventional case, in which the solder ball only lies flatly on a planar bond pad.

Similarly, the anode-side Bragg reflector 4 of the XCSEL itself is also enclosed by the corresponding solder ball 9. Thus, when there is low heat input through the electronics system a substantial portion of the waste heat may also flow through this channel, as indicated in FIG. 5.

Thus, since the design according to the invention has no planar surface, in addition a self-planarizing flip chip technology is used in which the varying solder ball sizes perform the bridging of all height differences.

For the flip chip XCSEL according to FIG. 4, the novel approach in which the wafer surface is provided with a specialized three-dimensional design anyway also offers the possibility of producing at the same time mesas for the through contacting (10 in FIG. 4) and for forming mechanical fiber guides (F in FIG. 4) without significant extra effort. These are elements which do not directly rely on the X shape as a production tool, but which instead elegantly result from the novel process sequence which is made possible by the X shape.

FIG. 6 shows another example (detail) of a surface-emitting semiconductor laser according to the invention. This laser is characterized in that its mesa has not just one constriction E, but two constrictions E1 and E2 in its side flank. The two constrictions E1 and E2 are superposed, viewed perpendicular to the substrate base plane 1 (i.e., viewed in the direction of emission).

The following are situated on the substrate 1 (semiconductor substrate) in the given sequence: First, a first doping region (n-doped region) 2, on which the active region 3 is situated, and situated on the active region 3 is the second doping region 4 (which in the present case is likewise n-doped, and which is situated at the structure of the active region 3 as described below).

In an analogous manner as previously described for the surface-emitting semiconductor laser element of FIG. 3, a first side wall metal contact 6a and a first side wall heat dissipator 7a are situated in the region of elements 1 and 2, and a second side wall metal contact 6b and a second side wall heat dissipator 7b are situated in the region of element 4.

In contrast to the element shown in FIG. 3, however, the active region 3 has the following structure: From the side facing the substrate base 1, in the direction of the side facing away from the substrate base, the active region 3 has, first of all, a first active subregion 3-1 in which a first active layer A1 is centrally situated. A doping region (p-doped region) 15 is situated on this first subregion 3-1. This doping region then bears the second active subregion 3-2 having the active layer (second active layer A2) centrally located in this subregion 3-2.

Just beneath the first active layer A1, the mesa of the illustrated semiconductor laser element has a first indentation region, i.e., a first constriction E1 which, analogously to the case shown in FIG. 3, is essentially V-shaped. In the upper section of the p-doped region 15 and in the region beneath the second active layer A2 the semiconductor element has the second constriction E2, which likewise is essentially V-shaped, in this case the angle of the two V legs being approximately 1.5 times the angle for the first constriction E1. In the region of the lower V leg of the second constriction E2 facing the substrate 1, the mesa side wall, in a design which is analogous to 6a, 7a and 6b, 7b, bears a third side wall metal contact 6c and a third side wall heat dissipator 7c via which the p-doped zone 15 is electrically contacted. In the present case, this is achieved in such a way that a polymer layer 16 (back-etched polymer layer) is provided above the elements 6a, 7a situated on the substrate base 1 and completely filling in the first constriction E1, the height of the polymer layer extending to just below the p-doped region. The sections of the third side wall metal contact 6c and of the third side wall heat dissipator 7c which do not adjoin the mesa side wall (in region 15) are then situated on this polymer layer 16.

Thus, multiple constrictions (preferably stacked perpendicularly on top of one another, i.e., superposed as viewed in the direction of emission) may also be achieved according to the invention. This is used in particular to reduce the mode volume by stronger guiding, and to adapt the geometry of the current supply or the heat dissipation to special requirements. The invention may thus also be easily implemented in the field of three- or multiterminal-like components (VCSEL or XCSEL having multiple cascaded active regions, and/or VCSEL or XCSEL having an integrated photodetector layer).

The proposed flip chip-soldered XCSEL arrays according to the invention have already been completely produced as prototypes. Instead of CMOS chips, for test purposes the arrays have been integrated with silicon-based supports containing coplanar control lines for high-frequency characterization. The components have been extensively characterized in the flip chip-soldered state, and in comparison to conventional components show greatly improved thermal and dynamic properties.

As indicated in dashed lines in FIG. 4 (elements 13a, 13b), all portions of the substrate 13 (HL substrate) may also remain on the emitting surface of the doped region 2 (n Bragg stack) in order to allow more central current injection. This may be achieved by leaving the corresponding regions during the substrate etching.

Using the proposed technology, in initial testing it has been possible to reduce the thermal resistance by half compared to the best international values heretofore. Preliminary increases in the limiting frequencies by likewise approximately 50%, to 17 GHz thus far for flip chip-integrated substrate-remote lasers, show that the thermal improvements as described are not achieved at the expense of the dynamics, but, rather, benefit the dynamics as the result of lower internal temperatures for avoiding additional extrinsic parasitics. In addition, initial data transmission experiments have been carried out at the maximum data rate of 12.5 Gbit/s achievable with the available equipment, thus demonstrating the suitability of the technology for such applications.

As described above, the proposed invention shows the formation in active region 3 of a high-resistance or electrically blocking current constriction layer 5 having a reduced oxidation length. Alternatively, it is possible not only to minimize the oxidation length (using an annular oxidation region 5 with appropriately low extension), but to even eliminate the oxidation length. Therefore, it is not necessary to provide a corresponding constriction region 5: in the present case the geometric constriction was combined with the constriction resulting from an annular insulating layer, but may also be used alone, i.e., without an additional lateral oxidation layer (insulating diaphragm).

The first prototypes of the XCSEL according to the invention have shown no particular vulnerabilities under the harsh laboratory environment, and have permitted extensive, problem-free characterization over a fairly long period without special precautions.

As an alternative to the embodiments described above, the following variants may also be implemented within the scope of the invention:
Non-circular base surfaces of the mesas are also possible (for example, elliptical or polygonal base surfaces).
Other coatings besides the typical metals are possible as side wall heat dissipators, for example:
   Since MBE also provides targeted deposition, after the profile etching it is also conceivable to overgrow the flanks in a second MBE growth step (for good contacts and laterally varying doping profiles, for example). This is possible in particular due to the fact that the XCSEL profiles themselves represent the masks for structured deposition, so that temperature-sensitive materials such as photoresists, which would not survive the temperatures of the MBE, are not necessary.
Partially dielectric DBRs are also possible: The described lateral contacting in particular may be advantageously combined with DBRs, which are partially composed of dielectrical layers such as SiO₂, TiO₂, Al₂O₃, and others, provided that a lateral etching rate differential exists.
The invention may be implemented in various material systems, and thus for various wavelength ranges:
   Since the profile control via the epitaxial layer structure does not limit the choice of wavelengths, the design is not tied to a given wavelength range, but instead supports, for example, in addition to the shorter wavelengths in the visible range (380 to 780 nm) via data communication (780 to 1000 nm), also the longer wavelength ranges of 1000 to 1650 nm. In particular in other material systems (InGaAsP/InP, for example) in which selective lateral oxidation has an unsatisfactory function (excessively low oxidation rates or low selectivity), the indentation is able to greatly reduce the profile of the oxidation width, and even totally eliminate it in the extreme case. Etching rate differentials between reflector layers may be provided more easily in numerous material systems, using a large number of available etchants, and may be adapted more easily to the particular demands, than for the selective lateral oxidation of aluminum-rich layers which has proven successful in AlGaAs.
The substrate of the flip chip XCSEL (FC-XCSEL) shown in FIG. 4 is removed in order to allow substrate-side emission at 850 nm. The substrate may be retained for other wavelengths for which the substrate is transparent (980 nm, for example).
FC-XCSEL: The through-contacting mesa (element 10 in FIG. 4) may be implemented in other ways (with/without a triangular base, with a pyramidal shape, wider/thinner, higher/deeper, etc.).
FC-XCSEL: The fiber guide may have a different geometry, in particular steep walls similar to the through-contacting mesa. In that case, the flat underside of an optical element may be flatly mounted in abutment, so that at the same time, for alignment in the plane (x-y plane) an angle error may also be avoided, even for a single component. On the other hand, for the array an angle error is avoided by mounting numerous identical elements.
FC-XCSEL: In addition to two-dimensional arrays, the solder configuration shown may also be used on individual surface-soldered components or one-dimensional arrays.

What is claimed is:

1. A surface emitting semiconductor laser having a vertical resonator, comprising
a substrate base section and
a mesa (M) situated on and/or at the substrate base section, wherein the mesa, viewed essentially perpendicular to the substrate base section, includes: at least part of a first doping region facing the substrate base section, at least part of a second doping region facing away from the substrate base section, and an active region situated between the first and the second doping regions, the active region having at least one active layer (A) having a laser-emitting zone which emits essentially perpendicular to the active layer,
wherein
the mesa (M), in at least a partial section of its side flank, has at least one constriction (E).

2. The surface emitting semiconductor laser according to claim 1,
wherein
the plane of the constriction (E) extends essentially parallel to the active layer and/or in that the mesa (M) has multiple constrictions (E1, E2) in at least one partial section of its side flank, wherein preferably at least two of these multiple constrictions are essentially superposed, viewed in the direction of emission.

3. The surface emitting semiconductor laser according to claim 1,
wherein
the constriction (E), viewed perpendicular to the substrate base plane, is provided at the level of the active layer (A), above the active layer (A) or below the active layer (A).

4. The surface emitting semiconductor laser according to claim 1,
wherein
viewed parallel to the plane of the constriction (E), the ratio of the surface area of the constriction to the maximum surface area of the first and/or the second doping region is less than 0.5, preferably less than 0.33, preferably less than 0.25, preferably less than 0.2.

5. The surface emitting semiconductor laser according to claim 1,
wherein
the mesa has an approximately X-shaped, double truncated cone-shaped and/or diabolo-like cross section in the region of the constriction (E), viewed perpendicular to the substrate base plane.

6. The surface emitting semiconductor laser according to claim 1,
wherein
at least a partial section of the mesa surface in the vicinity of the first doping region and/or in the vicinity of the second doping region extends at an angle (α) of greater than 45°, preferably greater than 55°, preferably greater than 60°, relative to the perpendicular to the substrate base.

7. The surface emitting semiconductor laser according to claim 6,
wherein
a first partial section of the mesa surface in the vicinity of the second doping region situated on the side of the active region facing away from the substrate base extends essentially parallel to the perpendicular to the substrate base, and a second partial section of the mesa surface in the vicinity of the second doping region extends essentially at an angle (α) of greater than 45°, preferably greater than 55°, preferably greater than 60°, relative to the perpendicular to the substrate base, wherein, viewed from the second partial section, the first partial section is provided on the side opposite from the substrate base section.

8. The surface emitting semiconductor laser according to claim 7,
wherein
the ratio of the extension in the direction of the perpendicular to the substrate base of the first partial section to that of the second partial section is between 1:1.5 and 1:2.5, preferably 1:2.

9. The surface emitting semiconductor laser according to claim 1,
wherein
a high-resistance or electrically blocking current constriction layer is provided in the active region.

10. The surface emitting semiconductor laser according to claim 9,
wherein
the high-resistance or electrically blocking current constriction layer is provided in the region of the constriction,
and/or
the high-resistance or electrically blocking current constriction layer is formed by a preferably annular oxidation layer.

11. The surface emitting semiconductor laser according to claim 1,
wherein
a first side wall metal contact is situated in the vicinity of the first doping region, adjacent to same and at least partially covering same in the mesa flank region,
and/or
a second side wall metal contact situated in the vicinity of the second doping region, adjacent to same and at least partially covering same in the mesa flank region.

12. The surface emitting semiconductor laser according to claim 11,
wherein
the first and/or the second side wall metal contact also at least partially cover(s) the active region in the mesa flank region.

13. The surface emitting semiconductor laser according to claim 11,
wherein
the first and/or the second side wall metal contact contain(s) or is/are composed of an Au—Ge—Ni alloy and/or a Pd/AuBe/Pt/Au alloy, a Pd/Ti/Pt/Au alloy, a Ge/Au/Ni/Au alloy, and/or a Pd/Ge/Pt/Au alloy.

14. The surface emitting semiconductor laser according to claim 1,
wherein
a first side wall heat dissipator situated at least partially in the mesa flank region of the first doping region,
and/or
a second side wall heat dissipator situated at least partially in the mesa flank region of the second doping region.

15. The surface emitting semiconductor laser according to claim 11,
wherein
a first side wall heat dissipator is situated adjacent to the first side wall metal contact, and at least partially covers same in the mesa flank region,
and/or
a second side wall heat dissipator is situated adjacent to the second side wall metal contact, and at least partially covers same in the mesa flank region.

16. The surface emitting semiconductor laser according to claim 14,
wherein
the first and/or the second side wall heat dissipator contain(s) or is/are composed of a material having a thermal conductivity greater than 0.5 W/cm/K, and/or Au, Cu, Ag, Al, diamond, BN, SiC, AlN, and/or Si,
and/or
the first and/or the second side wall heat dissipator is/are provided essentially in the form of a layer having a thickness of 0.1 μm to 10 μm, in particular 0.2 μm to 5 μm.

17. The surface emitting semiconductor laser according to claim 14,
wherein
at least one heat sink, heat distributor, and/or heat dissipator is in thermal contact with the first and/or the second side wall heat dissipator.

18. The surface emitting semiconductor laser according to claim 1,
wherein
the first doping region includes a first Bragg reflector stack, and/or the second doping region includes a second Bragg reflector stack,
and/or
the first doping region is n-doped and the second doping region is p-doped, or vice versa.

19. The surface emitting semiconductor laser according to claim 18,
wherein
the first and/or the second doping region has, at least in places, a dopant concentration of greater than 10¹⁸ atoms/cm, preferably greater than 10²⁰ atoms/cm.

20. The surface emitting semiconductor laser according to claim 1,
wherein
the surface-emitting semiconductor laser is designed on the basis of an InAlGaAs material system.

21. The surface emitting semiconductor laser according to claim 1,
wherein
a substrate base section contains or is composed of Si, InP, and/or GaAs, and/or a polymer.

22. A system having at least one surface-emitting semiconductor laser according to claim 1,
wherein
the one part of the substrate of the system forming the substrate base section of at least one of the semiconductor lasers is situated and/or shaped in such a way that in the region of its constriction (E), the mesa (M) of this semiconductor laser is bordered by this substrate base section in an at least partially positive-fit and/or force-fit manner.

23. The system according to the claim 22,
wherein
the mesa (M) of the at least one semiconductor laser is bordered in a free-floating manner, and/or the underside of this mesa facing the substrate base section and the top side of this mesa facing away from the substrate base section are not supported by the substrate base section or a portion thereof.

24. The system according to claim 22,
wherein
the underside of the mesa (M) of the at least one semiconductor laser facing the substrate base section is partially supported and/or covered by the substrate base section or a portion thereof.

25. The system according to claim 22, wherein the at least one semiconductor laser comprises a first side wall metal contact situated in the vicinity of the first doping region, adjacent to same and at least partially covering same in the mesa flank region,
and/or
a second side wall metal contact situated in the vicinity of the second doping region, adjacent to same and at least partially covering same in the mesa flank region,
wherein
the substrate base section of the at least one semiconductor laser together with the first and/or the second side wall metal contact and/or the first and/or the second side wall heat dissipator are situated and/or shaped in such a way that the referenced elements border the mesa (M) of the at least one semiconductor laser in the region of the constriction (E) of the mesa in a positive-fit and/or force-fit manner.

26. The system according to claim 22,
wherein
the substrate base section of the at least one semiconductor laser is situated and/or shaped in such a way that a mechanical guide structure (F) for at least one optical element, in particular a glass fiber, a glass fiber bundle, a microlens, and/or a microlens array, is formed by at least one partial section of this substrate base section.

27. The system according to claim 26,
wherein
an optical element is integrated into and/or situated adjacent to the guide structure in such a way that an interspace (Z) is provided between at least a partial section of the guide structure (F) and/or at least a partial section of the first doping region of the at least one semiconductor laser and at least a partial section of the optical element.

28. The system according to claim 27,
comprising
an interspace which is at least partially fillable and/or filled with a transparent fluid and/or a transparent solid-state material, in particular an adhesive, and/or an interspace which is provided at least partially for a transparent fluid, in particular a cooling gas and/or a cooling liquid, to flow through the interspace.

29. The system according to claim 28,
wherein
the transparent fluid and/or the transparent solid-state material has an optical index of refraction which is adapted to the optical index of refraction of the optical element and/or to the wavelength of the emittable and/or emitted laser light of the at least one semiconductor laser,
and/or
the transparent fluid and/or the transparent solid-state material has an optical index of refraction which is adapted to the width of the interspace between at least the partial section of the guide structure (F) and/or at least the partial section of the first doping region of the at least one semiconductor laser, and at least the partial section of the optical element.

30. The system according to claim 22,
wherein
the mesa of the at least one semiconductor laser is partially integrated into a bond pad and/or a solder, and/or is partially enclosed by the bond pad and/or solder.

31. The system according to claim 30,
wherein
the second doping region of the mesa facing away from the substrate base section is at least partially integrated into the bond pad and/or solder, and/or is at least partially enclosed by same.

32. The system according to claim 30 wherein a first side wall metal contact is situated in the vicinity of the first doping region, adjacent to same and at least partially covering same in the mesa flank region,
and/or
a second side wall metal contact situated in the vicinity of the second doping region, adjacent to same and at least partially covering same in the mesa flank region,
wherein
the first and/or the second side wall metal contact and/or a first and/or second side wall heat dissipator is/are at least partially situated between the bond pad and/or solder and the mesa (M).

33. The system according to claim 22,
wherein
the one part of the substrate of the system forming the substrate base section of the at least one semiconductor laser has an electrical through contacting which is separated at a distance from the border of the mesa.

34. The system according to claim 33,
wherein
the through contacting is provided in the form of a through-contacting mesa (DM).

35. The system according to claim 34,
wherein
the through-contacting mesa (DM) is partially integrated into a through contacting bond pad and/or through contacting solder, and/or is partially enclosed by the through contacting bond pad and/or through contacting solder.

36. The system according to claim 30,
wherein
the bond pad and/or the solder, and/or the through contacting bond pad and/or the through contacting solder, has/have or is/are composed of a soldering material.

37. The system according to claim 30,
comprising
a chip, in particular a CMOS chip, which is mechanically connected to the bond pad and/or solder, and/or to the through contacting bond pad and/or the through contacting solder (11).

38. The system according to claim 22 comprising multiple semiconductor lasers, and provided in the form of a matrix (array).

39. A method for manufacturing a surface-emitting semiconductor laser having a vertical resonator,
wherein a substrate base section and a mesa (M) situated on and/or at the substrate base section are formed by wet etching and/or dry etching,
wherein the mesa, viewed essentially perpendicular to the substrate base plane, includes: at least part of a first doping region facing the substrate base section, at least part of a second doping region facing away from the substrate base section, and an active region situated between the first and the second doping regions, the active region having at least one active layer (A) having a laser-emitting zone which emits essentially perpendicular to the active layer,
and wherein at least one constriction (E) is formed in at least a partial section of the side flank of the mesa (M) by the wet etching and/or the dry etching.

40. The method according to the claim 39,
wherein
a semiconductor laser or a system is formed.

41. The method according to claim 39,
wherein
the shaping of the mesa (M) of at least one semiconductor laser is carried out in a single etching step which includes the entire layer structure.

42. The method according to claim 39,
wherein
a side wall contact and/or a side wall heat dissipator of at least one semiconductor laser is/are defined and deposited as shadow masks by using mesa overhangs.

43. The method according to claim 39,
wherein
the first and/or a second side wall metal contact and/or the first and/or a second side wall heat dissipator of at least one semiconductor laser is/are produced using a single vapor deposition step, in particular using a single PVD or CVD step, without breaking vacuum.

44. A method of using a surface-emitting semiconductor laser according to claim 1 in the field of data transmission, in the field of sensor systems, in particular in the field of sensor systems within vehicles, in particular in the field of driver assistance systems, in particular for blind spot monitoring and/or collision recognition, or inside optical computer mice.
